(19) United States
(12) Patent Application Publication
(10) Pub. No.: US 2025/0022929 A1
(43) Pub. Date: Jan. 16, 2025

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP)

(73) Assignee: Japan Display Inc., Minato-ku, Tokyo (JP)

(21) Appl. No.: 18/897,128

(22) Filed: Sep. 26, 2024

Related U.S. Application Data
(63) Continuation of application No. PCT/JP2023/009877, filed on Mar. 14, 2023.

(30) Foreign Application Priority Data
Mar. 30, 2022 (JP) 2022-057453

(51) Int. Cl. H01L 29/423; H01L 29/49; H01L 29/786

(52) U.S. Cl. CPC H01L 29/42384; H01L 29/4966; H01L 29/7869

(57) ABSTRACT

A semiconductor device according to an embodiment includes an oxide semiconductor layer provided above an insulating surface, a gate insulating layer provided above the oxide semiconductor layer, and a gate electrode provided above the oxide semiconductor layer via the gate insulating layer, wherein the gate electrode has a titanium-containing layer and a conductive layer in order from the gate insulating layer side, the gate insulating layer includes a first region overlapping the gate electrode and a second region not overlapping the gate electrode, and a thickness of the titanium-containing layer is 50% or less than a thickness of the gate insulating layer in the first region.

### CROSS REFERENCE TO RELATED APPLICATIONS

This application is a Continuation of International Patent Application No. PCT/JP2023/009877, filed on Mar. 14, 2023, which claims the benefit of priority to Japanese Patent Application No. 2022-057453, filed on Mar. 30, 2022, the entire contents of which are incorporated herein by reference.

### FIELD

An embodiment of the present invention relates to a semiconductor device and a method for manufacturing a semiconductor device. In particular, an embodiment of the present invention relates to a semiconductor device and a method for manufacturing a semiconductor device in which an oxide semiconductor is used as a channel.

### BACKGROUND

In recent years, a semiconductor device in which an oxide semiconductor is used for a channel instead of amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which the oxide semiconductor is used for the channel can be formed with a simple structure and a low-temperature process, similar to a semiconductor device in which amorphous silicon is used as a channel. The semiconductor device in which the oxide semiconductor is used for the channel is known to have higher mobility than the semiconductor device in which amorphous silicon is used for the channel.

It is essential to supply oxygen to an oxide semiconductor layer in the manufacturing process and to reduce the oxygen deficiencies formed in the oxide semiconductor layer in order for the semiconductor device in which the oxide semiconductor is used for the channel to perform a stable operation. For example, a technique of forming an insulating layer covering the oxide semiconductor layer under the condition that the insulating layer contains more oxygen is disclosed as one method of supplying oxygen to the oxide semiconductor layer.

### SUMMARY

A semiconductor device according to an embodiment of the present invention includes an oxide semiconductor layer provided above an insulating surface, a gate insulating layer provided above the oxide semiconductor layer, and a gate electrode provided above the oxide semiconductor layer via the gate insulating layer, wherein the gate electrode has a titanium-containing layer and a conductive layer in order from the gate insulating layer side, the gate insulating layer includes a first region overlapping the gate electrode and a second region not overlapping the gate electrode, and a thickness of the titanium-containing layer is 50% or less than a thickness of the gate insulating layer in the first region.

### BRIEF DESCRIPTION OF DRAWINGS

FIG. 1A is a cross-sectional view showing an outline of a semiconductor device according to an embodiment of the present invention.

FIG. 1B is an enlarged magnified view of a portion of a semiconductor device shown in FIG. 1A.

FIG. 2 is a plan view showing an outline of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10A is a cross-sectional view showing a method for manufacturing a semiconductor device according to an embodiment of the present invention.

FIG. 10B is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing an outline of a semiconductor device according to an embodiment of the present invention.

FIG. 13A is a cross-sectional view showing an outline of a semiconductor device according to an embodiment of the present invention.

FIG. 13B an enlarged magnified view of a portion of a semiconductor device shown in FIG. 13A.

FIG. 14 is a sequence diagram showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a cross-sectional view showing a method for manufacturing a semiconductor device according to an embodiment of the present invention.

FIG. 19 is a cross-sectional view showing a method for manufacturing a semiconductor device according to an embodiment of the present invention.

FIG. 20 is a cross-sectional view showing a method for manufacturing a semiconductor device according to an embodiment of the present invention.

FIG. 21 is a cross-sectional view showing a method for manufacturing a semiconductor device according to a modification of an embodiment of the present invention.

FIG. 22 is a cross-sectional view showing a method for manufacturing a semiconductor device according to an embodiment of the present invention.

FIG. 23 is a cross-sectional view showing a method for manufacturing a semiconductor device according to a modification of an embodiment of the present invention.

FIG. 24 is a plan view showing an outline of a semiconductor device according to an embodiment of the present invention.

FIG. 25 is a plan view showing an outline of a display device according to an embodiment of the present invention.

FIG. 26 is a block diagram showing a circuit configuration of a display device according to an embodiment of the present invention.

FIG. 27 is a circuit diagram showing a pixel circuit of a display device according to an embodiment of the present invention.

FIG. 28 is a cross-sectional view showing an outline of a display device according to an embodiment of the present invention.

FIG. 29 is a plan view of a pixel electrode and a common electrode of a display device according to an embodiment of the present invention.

FIG. 30 is a circuit diagram showing a pixel circuit of a display device according to an embodiment of the present invention.

FIG. 31 is a cross-sectional view showing an outline of a display device according to an embodiment of the present invention.

FIG. 32 is a diagram showing the electrical characteristics of a semiconductor device according to an embodiment of the present invention.

FIG. 33 is a diagram showing the electrical characteristics of a semiconductor device according to an embodiment of the present invention.

FIG. 34 is a diagram showing the electrical characteristics of a semiconductor device according to an embodiment of the present invention.

FIG. 35 is a diagram showing the electrical characteristics of a semiconductor device according to an embodiment of the present invention.

FIG. 36 is a diagram showing the electrical characteristics of a semiconductor device according to an embodiment of the present invention.

FIG. 37 is a diagram showing the electrical characteristics of a semiconductor device according to an embodiment of the present invention.

FIG. 38 is a diagram showing an in-plane variation of a threshold voltage of a semiconductor device according to an embodiment of the present invention.

FIG. 39 is a diagram showing the electrical characteristics of a semiconductor device according to an embodiment of the present invention.

FIG. 40 is a diagram showing the electrical characteristics of a semiconductor device according to an embodiment of the present invention.

FIG. 41 is a diagram showing the electrical characteristics of a semiconductor device according to an embodiment of the present invention.

FIG. 42 is a diagram showing a relationship between a thickness of a first region of a gate insulating layer and a threshold voltage of a semiconductor device according to an embodiment of the present invention.

### DESCRIPTION OF EMBODIMENTS

However, the insulating layer formed with more oxygen-containing conditions contains more defects. As a result, abnormal characteristics of the semiconductor device or a variation in characteristics in a reliability test occur, which are considered to be caused by electrons becoming trapped in the defect. On the other hand, if an insulating layer with fewer defects is used, oxygen in the insulating layer cannot be increased. Therefore, sufficient oxygen cannot be supplied from the insulating layer to the oxide semiconductor layer. As described above, there is a demand for realizing a structure capable of repairing oxygen deficiencies formed in the oxide semiconductor layer while reducing defects in the insulating layer that cause the variation in characteristics of the semiconductor device.

Further, a semiconductor device with high mobility can be obtained by relatively increasing a ratio of indium contained in the oxide semiconductor layer. However, if the ratio of indium contained in the oxide semiconductor layer is high, oxygen deficiencies are likely to be formed in the oxide semiconductor layer. Therefore, in order to realize high mobility while maintaining high reliability, it is necessary to devise a configuration of the insulating layer around the oxide semiconductor layer.

An object of the embodiment of the present invention is to realize a highly reliable semiconductor device having high mobility.

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

“Semiconductor device” refers to all devices that can function by utilizing semiconductor characteristics. Transistors and semiconductor circuits region form of semiconductor device. For example, a semiconductor device may be used in an integrated circuit (IC) such as a micro-processing unit (MPU) or a memory circuit in addition to a transistor used in a display device.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer and an organic EL display device including an organic EL layer as the display device, the structure in the present embodiment can be applied to a display device including the other electro-optic layers described above.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

The expressions “a includes A, B, or C”, “a includes any of A, B, and C”, and “α includes one selected from a group consisting of A, B, and C” do not exclude the case where a includes multiple combinations of A to C unless otherwise specified. Furthermore, these expressions do not exclude the case where a includes other elements.

In addition, the following embodiments may be combined with each other as long as there is no technical contradiction.

### First Embodiment

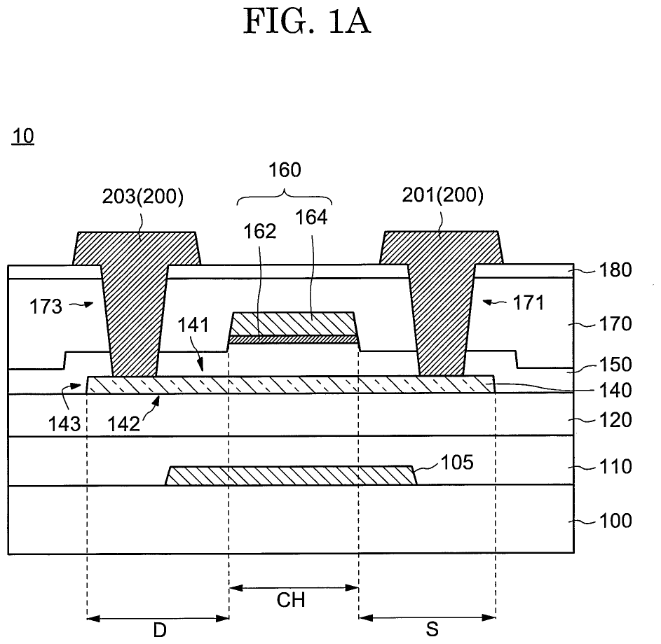

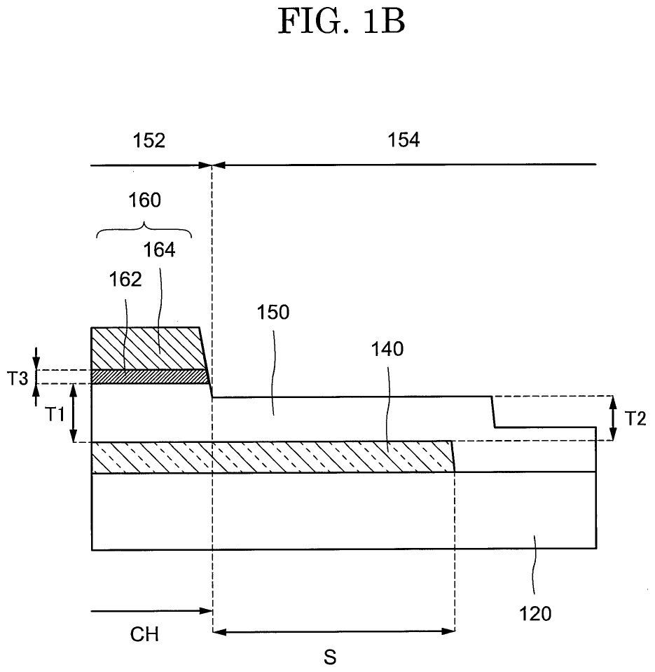

A semiconductor device according to an embodiment of the present invention will be described with reference to FIG. 1A to FIG. 12.

### [Configuration of Semiconductor Device 10]

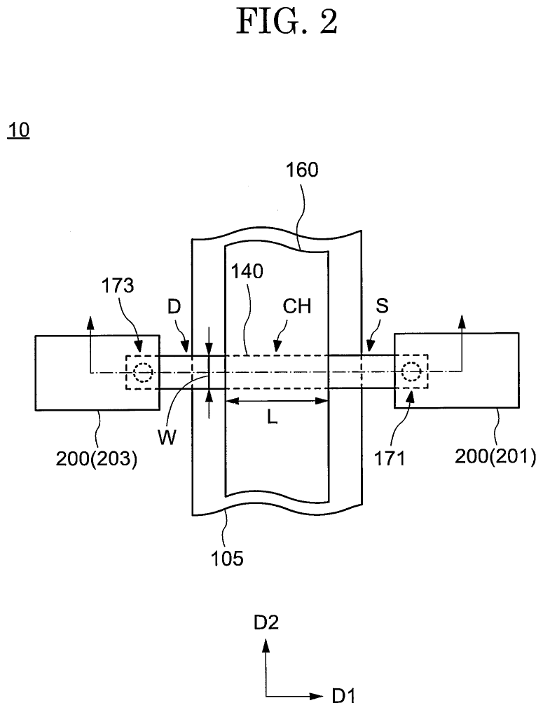

A configuration of a semiconductor device 10 according to an embodiment of the present invention will be described with reference to FIG. 1A and FIG. 2. FIG. 1A is a cross-sectional view showing an outline of a semiconductor device according to an embodiment of the present invention. FIG. 1B is an enlarged magnified view of a portion of a semiconductor device shown in FIG. 1A. FIG. 2 is a plan view showing an outline of a semiconductor device according to an embodiment of the present invention.

As shown in FIG. 1A, the semiconductor device 10 is arranged above a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. If the source electrode 201 and the drain electrode 203 are not specifically distinguished from each other, they may be referred to as a source-drain electrode 200.

The gate electrode 105 is arranged above the substrate 100. The gate insulating layer 110 and the gate insulating layer 120 are arranged above the substrate 100 and the gate electrode 105. The metal oxide layer 130 is arranged above the gate insulating layer 120. The oxide semiconductor layer 140 is in contact with the metal oxide layer 130. In the main surface of the oxide semiconductor layer 140, a surface in contact with the gate insulating layer 120 is referred to as a lower surface 142.

The gate electrode 160 faces the oxide semiconductor layer 140. The gate insulating layer 150 is arranged between the oxide semiconductor layer 140 and the gate electrode 160. The gate insulating layer 150 is in contact with the oxide semiconductor layer 140. Among the main surface of the oxide semiconductor layer 140, a surface in contact with the gate insulating layer 150 is referred to as an upper surface 141. A surface between the upper surface 141 and the lower surface 142 is referred to as a side surface 143. The insulating layers 170 and 180 are arranged above the gate insulating layer 150 and the gate electrode 160. Openings 171 and 173 that reach the oxide semiconductor layer 140 are arranged in the insulating layers 170 and 180. The source electrode 201 is arranged inside the opening 171. The source electrode 201 is in contact with the oxide semiconductor layer 140 at an bottom of the opening 171. The drain electrode 203 is arranged inside the opening 173. The drain electrode 203 is in contact with the oxide semiconductor layer 140 at an bottom of the opening 173.

The gate electrode 105 has a function as a bottom-gate of the semiconductor device 10 and a function as a light-shielding film for the oxide semiconductor layer 140. The gate insulating layer 110 has a function as a barrier film for shielding impurities that diffuse from the substrate 100 toward the oxide semiconductor layer 140. The gate insulating layers 110 and 120 have a function as a gate insulating layer for the bottom-gate.

The oxide semiconductor layer 140 is divided into a source region S, a drain region D, and a channel region CH. The channel region CH is an region of the oxide semiconductor layer 140 vertically below the gate electrode 160. The source region S is an region of the oxide semiconductor layer 140 that does not overlap the gate electrode 160 and is closer to the source electrode 201 than the channel region CH. The drain region D is an region of the oxide semiconductor layer 140 that does not overlap the gate electrode 160 and is closer to the drain electrode 203 than the channel region CH. The oxide semiconductor layer 140 in the channel region CH has physical properties as a semiconductor. The oxide semiconductor layer 140 in the source region S and the drain region D has physical properties as a conductor.

The gate electrode 160 has a function as a top-gate of the semiconductor device 10 and a light-shielding film for the oxide semiconductor layer 140. The gate insulating layer 150 has a function as a gate insulating layer for the top-gate, and has a function of releasing oxygen by a heat treatment in a manufacturing process. The insulating layers 170 and 180 insulate the gate electrode 160 and the source-drain electrode 200 and have a function of reducing parasitic capacitance therebetween. Operations of the semiconductor device 10 are controlled mainly by a voltage supplied to the gate electrode 160. An auxiliary voltage is supplied to the gate electrode 105. However, in the case of using the gate electrode 105 simply as a light-shielding film, a specific voltage is not supplied to the gate electrode 105, and the gate electrode 105 may be in a floating state. That is, the gate electrode 105 may simply be referred to as a “light-shielding film.”

Conventionally, in a transistor in which an oxide semiconductor is used as the channel, molybdenum-tungsten, for example, is used as the gate wiring (gate electrode). The transistor in which a molybdenum-tungsten layer is used as the gate wiring have a problem that a drain current Id begins to flow when a gate voltage Vg is lower than 0V, so-called normally-on. During a heat treatment in a transistor manufacturing process, oxygen contained in a gate insulating layer is transferred to the molybdenum-tungsten layer and is not supplied to a oxide semiconductor layer. As a result, oxygen defects in the oxide semiconductor layer cannot be sufficiently repaired, and the electrical characteristics of the transistor become normally-on.

The gate wiring is a structure of a titanium layer under a molybdenum-tungsten layer and a stacked structure of a titanium layer and a molybdenum-tungsten layer, which prevents the transistor from being normally-on. The titanium layer suppresses a transfer of hydrogen and oxygen contained in the gate insulating layer 150 through the titanium layer to the conductive layer 164 during heat treatment in the transistor manufacturing process. On the other hand, an etching rate of the titanium layer is slower than that of the molybdenum-tungsten layer. Therefore, a thicker titanium layer increases the processing time of dry etching, resulting in in-plane variation in a line width of the gate wiring. In addition, the gate insulating layer is removed by over-etching, resulting in in-plane variation in a thickness of the gate insulating layer. An effect of in-plane variation is particularly significant when large-region substrates of 6th generation or larger are used as a substrate for manufacturing a transistor. When a thickness of the titanium layer is thin, it cannot block the oxygen contained in the gate insulating layer 150 and reacts with the conductive layer 164. As a result, the electrical characteristics of the semiconductor device to be normally-on, resulting in large variations in the electrical characteristics. These factors cause the problem of variations in the electrical characteristics of the transistor within the substrate plane.

In a transistor in which an oxide semiconductor is used for a channel, a short-channel transistor can be formed by controlling a channel length by forming source and drain regions by ion implantation using a gate wiring as a mask. Generally, in a manufacturing process for a transistor in which low-temperature polysilicon is used for a channel, which uses ion implantation, a thickness of a gate insulating layer is as thin as 100 nm. Therefore, most ion implanters are designed to implant at an acceleration that assumes a gate insulating layer thickness of about 100 nm. To form the source and drain regions of the transistor with an oxide semiconductor channel using such an ion implanter, a thickness of the gate insulating layer must be about 100 nm. However, if a thickness of the gate insulating layer is about 100 nm in a transistor in which an oxide semiconductor is used for a channel, the oxygen defects in the oxide semiconductor layer cannot be sufficiently repaired. This is because the amount of oxygen contained in the gate insulating layer is not sufficient. As a result, a problem occurs whereby the electrical characteristics of the transistor tend to be normally-on. Since the amount of oxygen must be secured by the thickness of the gate insulating layer, it is difficult to reduce the thickness of the gate insulating layer.

Therefore, an embodiment of the present invention provides a semiconductor device having normally-off electrical characteristics. In addition, an embodiment provides a semiconductor device in which the variation of electrical characteristics is suppressed within a substrate plane.

In an embodiment of the present invention, as shown in FIG. 1A and FIG. 1B, the gate electrode 160 has a titanium-containing layer 162 and a conductive layer 164, in order from the gate insulating layer 150 side. In this specification, the titanium-containing layer 162 is a layer that contains titanium as a major component, for example, titanium, titanium nitride, or titanium oxide. The titanium-containing layer 162 may be a titanium layer that contains at least one of nitrogen or oxygen. The titanium-containing layer 162 may be a stacked structure of a titanium layer and a nitrogen-containing titanium layer with nitrogen added to the titanium layer. The titanium-containing layer 162 may be a stacked structure of a titanium layer and an oxygen-containing titanium layer in which oxygen is added to the titanium layer. The titanium layer may include at least one of an oxidized region and a nitride region as the titanium-containing layer 162. Molybdenum, tungsten, or molybdenum-tungsten is used as the conductive layer 164.

The gate insulating layer 150 has a region overlapping the gate electrode 160 (called a first region 152) and a region not overlapping the gate electrode 160 (also called a second region 154). In other words, the region overlapping the gate electrode 160 is a region overlapping a channel region CH of the oxide semiconductor layer 140. A region not overlapping the gate electrode 160 includes a region overlapping a source region S and a drain region D of the oxide semiconductor layer 140 and a region in contact with the gate insulating layer 120.

As shown in FIG. 1B, a thickness T1 of the first region 152 is different from a thickness T2 of the second region 154 in the gate insulating layer 150. The thickness T1 of the first region 152 is a thickness of the gate insulating layer 150 when it is deposited in the manufacturing process. The thickness T2 of the second region 154 is a thickness formed by dry etching when the gate electrode 160 is formed.

As mentioned above, a thickness of the titanium-containing layer 162 affects the amount (thickness) of the gate insulating layer 150 that is removed in the gate electrode 160. Therefore, a thickness T3 of the titanium-containing layer 162 should be 50% or less of the thickness T1 in the first region 152. Preferably, the thickness T3 is 20% or more and 30% or less of the thickness T1. For example, the thickness T3 of the titanium-containing layer 162 should be 25 nm or more and 50 nm or less. When the titanium-containing layer 162 is not provided (i.e., when the thickness of the titanium-containing layer 162 is 0 nm), the electrical characteristics of the transistor will be normally-on.

If the thickness T3 of the titanium-containing layer 162 is less than 25 nm, hydrogen and oxygen contained in the gate insulating layer 150 will move to the conductive layer 164 through the titanium-containing layer during a heat treatment in the semiconductor device manufacturing process. As a result, even the oxygen that should be supplied to the oxide semiconductor layer 140 may move to the conductive layer 164, and the oxygen defects in the oxide semiconductor layer 140 may not be sufficiently repaired. Therefore, when the thickness T3 of the titanium-containing layer 162 is at least 25 nm or more, it is possible to suppress movement of oxygen contained in the gate insulating layer 150 to the conductive layer 164 through the titanium-containing layer during the heat treatment in the semiconductor device manufacturing process. As a result, the oxygen contained in the gate insulating layer 150 is supplied to the oxide semiconductor layer 140 during the heat treatment, thereby repairing the oxygen defects in the oxide semiconductor layer 140. Therefore, it is possible to suppress the transistor from becoming normally-on.

When the thickness T3 of the titanium-containing layer 162 is 50 nm or more, a dry etching process time becomes longer when forming the gate electrode 160, resulting in variations in a line width of a gate wiring. In addition, the gate insulating layer is removed by over-etching, resulting in variations in the thickness of the gate insulating layer. These factors cause variations in the electrical characteristics of the transistor within the substrate plane.

As explained above, the thickness T3 of the titanium-containing layer 162 should be 50% or less of the thickness T1 of the first region of the gate insulating layer 150, and preferably 20% or more and 30% or less. For example, the thickness T3 of the titanium-containing layer 162 is 25 nm or more and 50 nm or less. As a result, the electrical characteristics of the transistor are suppressed from becoming normally-on and variations in the electrical characteristics of the transistor within the substrate plane can be prevented.

The thickness of the first region T1 of the gate insulating layer 150 should be 100 nm or more and 125 nm or less. The thickness T3 of the titanium-containing layer 162 should be 25% or more and 70% or less of the thickness T2 of the second region 154. For example, the thickness T2 of the second region 154 of the gate insulating layer 150 should be 75 nm or more and 100 nm or less. When the thickness of the first region T1 of the gate insulating layer 150 is less than 100 nm, the electrical characteristics of the semiconductor device will be normally-on.

As mentioned above, an ion implanter is used to form the source region S and drain region D in the oxide semiconductor layer 140. When the thickness T2 of the second region 154 is more than 100 nm, impurities may not reach the oxide semiconductor layer 140. When there are in-plane variations in the thickness of the gate insulating layer 150, the impurities added to the source region S and the drain region D will be uneven, resulting in uneven electrical resistance which causes in-plane variations in the electrical characteristics of the transistor. The thickness T2 of the second region 154 of the gate insulating layer 150 determines the amount removed by over-etching when forming the gate electrode 160. Therefore, when the thickness of the first region 152 of the gate insulating layer 150 is less than 100 nm, the thickness T2 of the second region may be thinner than necessary. Therefore, the thickness T2 of the second region 154 of the gate insulating layer 150 should be 75 nm or more and 100 nm or less. As will be described below, in an embodiment of the present invention, even if the thickness of the gate insulating layer 150 is 100 nm or more and 125 nm or less, the electrical characteristics of the transistor can be suppressed to be normally-on.

In the present embodiment, although a configuration using a dual-gate transistor in which the gate electrode is arranged both above and below the oxide semiconductor layer as the semiconductor device 10 is exemplified, the configuration is not limited to this configuration. For example, a bottom-gate transistor in which the gate electrode is arranged only below the oxide semiconductor layer or a top-gate transistor in which the gate electrode is arranged only above the oxide semiconductor layer may be used as the semiconductor device 10. The above configuration is merely an embodiment, and the present invention is not limited to the above configuration.

As shown in FIG. 2, in a direction D1, a width of the gate electrode 105 is wider than a width of the gate electrode 160. The direction D1 is a direction connecting the source electrode 201 and the drain electrode 203 and indicates a channel length L of the semiconductor device 10. Specifically, a length of a region (channel region CH) where the oxide semiconductor layer 140 overlaps the gate electrode in the direction D1 is the channel L, and a width of the channel region CH in a direction D2 is a channel width W.

In the present embodiment, although a configuration in which the gate insulating layer 150 is formed on the entire surface and the openings 171 and 173 are arranged in the gate insulating layer 150 is exemplified, the configuration is not limited to this configuration. The gate insulating layer 150 may be patterned. For example, the gate insulating layer 150 may be patterned to expose the oxide semiconductor layer 140 in the source region S and the drain region D. That is, the gate insulating layer 150 in the source region S and the drain region D may be removed, and the oxide semiconductor layer 140 and the insulating layer 170 may be in contact with each other in these regions.

In FIG. 2, although a configuration in which the source-drain electrode 200 does not overlap the gate electrode 105 and the gate electrode 160 in a plan view is exemplified, the configuration is not limited to this configuration. For example, in a plan view, the source-drain electrode 200 may overlap at least one of the gate electrode 105 or the gate electrode 160. The above configuration is merely an embodiment, and the present invention is not limited to the above configuration.

### [Material of Each Member of Semiconductor Device 10]

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that deteriorate the translucency of the substrate 100 may be used. In the case where the semiconductor device 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used for the gate electrode 105, the gate electrode 160, and the source-drain electrode 200. For example, aluminum (AI), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys thereof or compounds thereof are used as these members. The above-described materials may be used in a single layer or in a stacked layer as the gate electrode 105, the gate electrode 160, and the source-drain electrode 200.

In this embodiment, a stacked structure of a titanium-containing layer 162 and a conductive layer 164 is used as the gate electrode 160. The materials used as the titanium-containing layer 162 and the conductive layer 164 are described above.

Common insulating materials are used for the gate insulating layers 110 and 120 and the insulating layers 170 and 180. For example, insulating layers such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) are used as the inorganic insulating layers.

Among the above-described insulating layers, the insulating layer containing oxygen is used as the gate insulating layer 150. For example, an inorganic insulating layer such as silicon oxide (SiOₓ), silicon oxynitride (SiOₓN_{y}), aluminum oxide (AlOₓ), and aluminum oxynitride (AlOₓN_{y}) is used as the gate insulating layer 150.

An insulating layer having a function of releasing oxygen by a heat treatment is used as the gate insulating layer 120. For example, the temperature of the heat treatment at which the gate insulating layer 120 releases oxygen is 600° C. or less, 500° C. or less, 450° C. or less, or 400° C. or less. That is, for example, in the case where the glass substrate is used as the substrate 100, the gate insulating layer 120 releases oxygen at the heat treatment temperature performed in the manufacturing process of the semiconductor device 10.

An insulating layer with few defects is used as the gate insulating layer 150. For example, when a composition ratio of oxygen in the gate insulating layer 150 is compared with a composition ratio of oxygen in an insulating layer (hereinafter referred to as “other insulating layer”) having a composition similar to that of the gate insulating layer 150, the composition ratio of oxygen in the gate insulating layer 150 is closer to the stoichiometric ratio with respect to the insulating layer than the composition ratio of oxygen in that other insulating layer. Specifically, in the case where silicon oxide (SiOₓ) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which no defects are observed when evaluated by electron-spin resonance (ESR) may be used as the gate insulating layer 150.

SiOₓN_{y} and AlOₓN_{y} described above are silicon compound and an aluminum compound containing nitrogen (N) in a ratio (x>y) smaller than that of oxygen (O). SiNₓO_{y} and AlNₓO_{y} are silicon compound and an aluminum compound containing oxygen in a ratio (x>y) smaller than that of nitrogen.

Although the details will be described later, a metal oxide containing aluminum as the main component is used as a metal oxide layer 190 used in the manufacturing process. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer 190. The “metal oxide layer containing aluminum as the main component” means that the ratio of aluminum contained in the metal oxide layer 190 is 1% or more of the total amount of the metal oxide layer 190. The ratio of aluminum contained in the metal oxide layer 190 may be 5% or more and 70% or less, 10% or more and 60% or less, or 30% or more and 50% or less of the total amount of the metal oxide layer 130. The above ratio may be a mass ratio or a weight ratio.

A metal oxide having semiconductor properties is used as the oxide semiconductor layer 140. For example, an oxide semiconductor containing two or more metals containing indium (In) is used as the oxide semiconductor layer 140. The ratio of indium to the entire oxide semiconductor layer 140 is 50% or more. At least one selected from the group of gallium (Ga), zinc (Zn), aluminum (Al), hafnium (Hf), yttrium (Y), zirconia (Zr), and lanthanoids is used as the oxide semiconductor layer 140 in addition to indium. Elements other than those described above may be used for the oxide semiconductor layer 140.

The oxide semiconductor layer 140 may be amorphous or crystalline. The oxide semiconductor layer 140 may be a mixed phase of amorphous and crystalline. Oxygen deficiencies are likely to be formed in the oxide semiconductor layer 140 in which the ratio of indium is 50% or more, as described below. Oxygen deficiencies are less likely to be formed in a crystalline oxide semiconductor as compared with an amorphous oxide semiconductor. Therefore, the oxide semiconductor layer 140 as described above is preferably crystalline.

### [Method for Manufacturing Semiconductor Device 10]

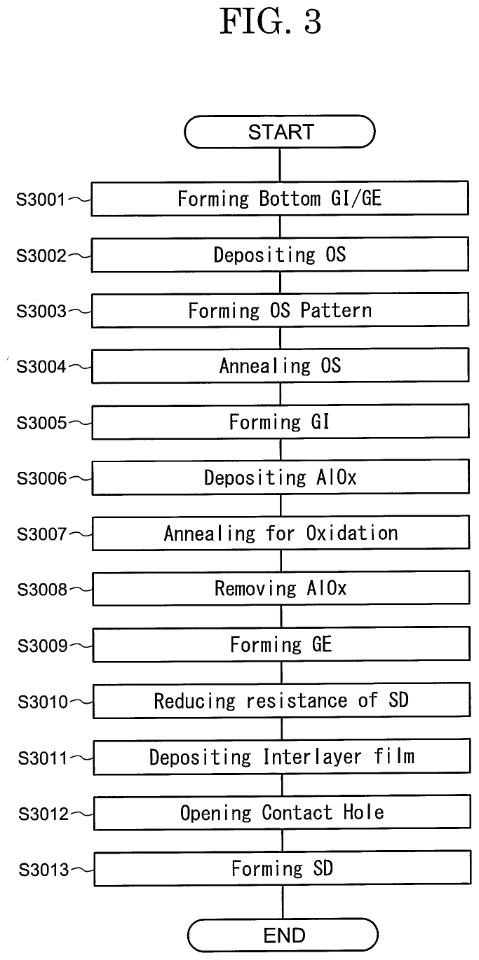

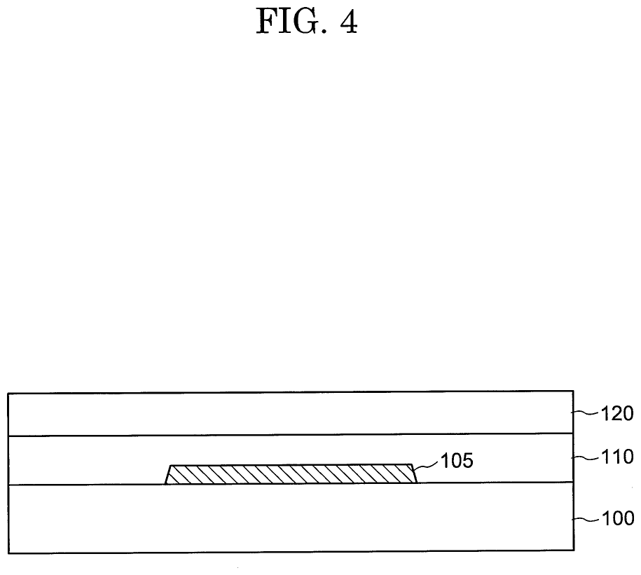

A method for manufacturing a semiconductor device according to an embodiment of the present invention will be described with reference to FIG. 3 to FIG. 12. FIG. 3 is a sequence diagram showing a method for manufacturing a semiconductor device according to an embodiment of the present invention. FIG. 4 to FIG. 12 are cross-sectional views showing a method for manufacturing a semiconductor device according to an embodiment of the present invention.

As shown in FIG. 3 and FIG. 4, the gate electrode 105 is formed on the substrate 100 as the bottom-gate, and the gate insulating layers 110 and 120 are formed on the gate electrode 105 (“Forming Bottom GI/GE” in step S3001 of FIG. 3). For example, silicon nitride is formed as the gate insulating layer 110. For example, silicon oxide is formed as the gate insulating layer 120. The gate insulating layers 110 and 120 are deposited by a CVD (Chemical Vapor Deposition) method.

Using silicon nitride as the gate insulating layer 110 allows the gate insulating layer 110 to block impurities that diffuse, for example, from the substrate 100 toward the oxide semiconductor layer 140. The silicon oxide used as the gate insulating layer 120 is silicon oxide having a physical property of releasing oxygen by heat treatment.

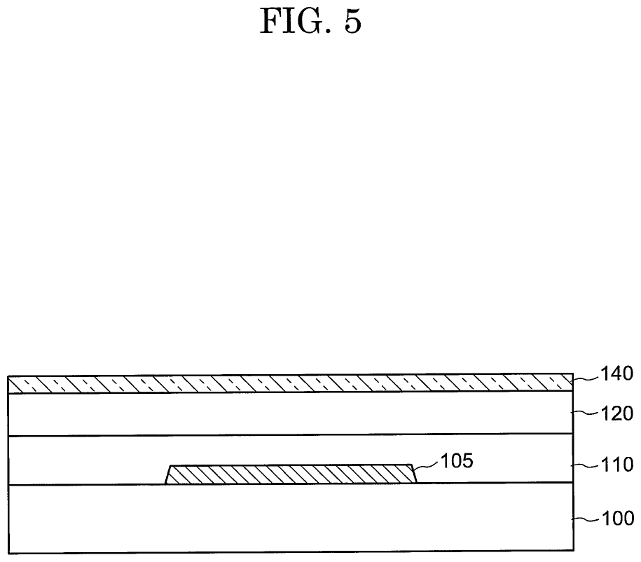

As shown in FIG. 3 and FIG. 5, the oxide semiconductor layer 140 is formed on the gate insulating layer 120 (“Depositing OS” in step S3002 of FIG. 3). For this process, it can be said that the gate insulating layer 140 is formed above the substrate 100. The oxide semiconductor layer 140 is deposited by a sputtering method or an atomic layer deposition method (ALD).

For example, a thickness of the oxide semiconductor layer 140 is 10 nm or more and 100 nm or less, 15 nm or more and 70 nm or less, or 20 nm or more and 40 nm or less. In this embodiment, an oxide containing indium (In) and gallium (Ga) is used as the oxide semiconductor layer 140. The oxide semiconductor layer 140 before the heat treatment (OS anneal) described later is amorphous. In addition, the oxide semiconductor layer 140 may be an oxide containing indium (In), gallium (Ga), and zinc (Zn), the so-called IGZO.

When the oxide semiconductor layer 140 is crystallized by the OS anneal described later, the oxide semiconductor layer 140 after the deposition and before the OS anneal is preferably in an amorphous state (a state of low crystalline components of the oxide semiconductor are fewer). That is, deposition conditions of the oxide semiconductor layer 140 are preferred to be a condition such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, microcrystals are occurred in the oxide semiconductor layer 140 immediately after the deposition process. The microcrystals inhibit crystallization by subsequent OS anneal. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is 100° C. or less, 70° C. or less, 50° C. or less, or 30° C. or less. As described above, depositing the oxide semiconductor layer 140 while cooling the object to be deposited makes it possible to deposit the oxide semiconductor layer 140 with few crystalline components in a state immediately after the deposition.

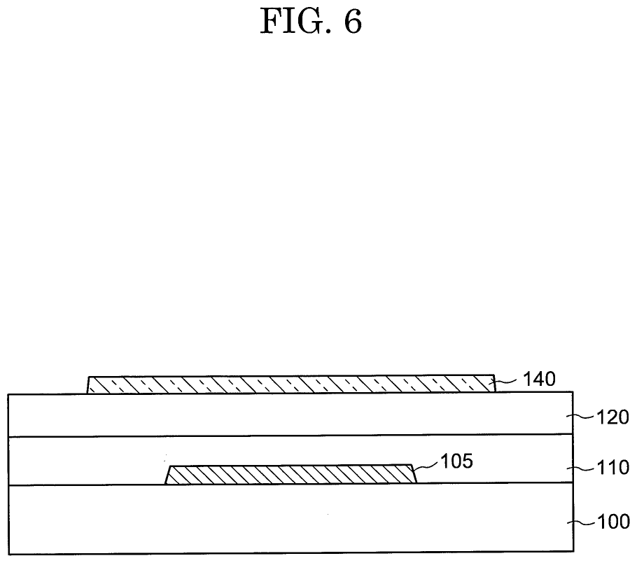

As shown in FIG. 3 and FIG. 6, a pattern of the oxide semiconductor layer 140 is formed (“Forming OS Pattern” in step S3003 of FIG. 3). Although not shown, a resist mask is formed on the oxide semiconductor layer 140, and the oxide semiconductor layer 140 is etched using the resist mask. Wet etching may be used, or dry etching may be used as the etching of the oxide semiconductor layer 140. The wet etching may include etching using an acidic etchant. For example, oxalic acid or hydrofluoric acid may be used as the etchant.

Heat treatment (OS anneal) (“Annealing OS” in step S3004 of FIG. 3) is performed on the oxide semiconductor layer 140 after the pattern of the oxide semiconductor layer 140 is formed. In the present embodiment, the oxide semiconductor layer 140 is crystallized by the OS anneal.

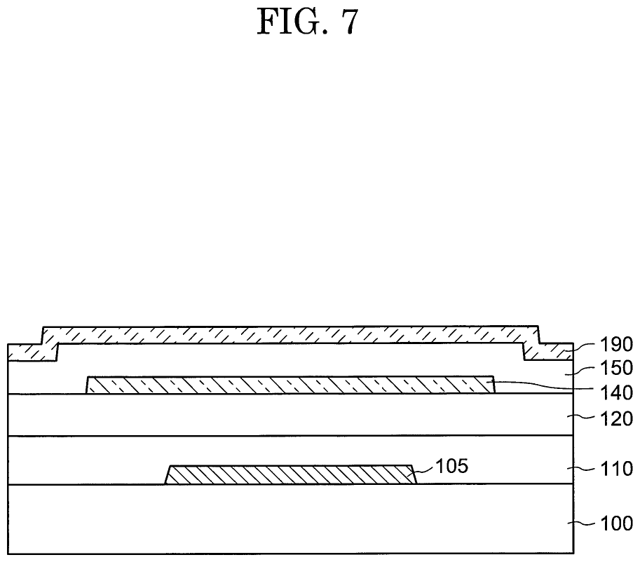

As shown in FIG. 3 and FIG. 7, the gate insulating layer 150 is deposited on the oxide semiconductor layer 140 (“Forming GI” in step S3005 of FIG. 3). For example, silicon oxide is formed as the gate insulating layer 150. The gate insulating layer 150 is formed by the CVD method. For example, the gate insulating layer 150 may be deposited at a deposition temperature of 350° C. or higher in order to form an insulating layer having few defects as described above. In this embodiment, a thickness of the gate insulating layer 150 is 100 nm or more and 125 nm or less. A thickness of the gate insulating layer 150 corresponds to a thickness T1 of the first region 152. For example, silicon oxide is used as the gate insulating layer. A process of implanting oxygen may be performed on a part of the gate insulating layer 150 after the gate insulating layer 150 is deposited. The gate insulating layer 150 may be referred to as a “first insulating layer.” The metal oxide layer 190 is deposited on the gate insulating layer 150 (“Depositing AlOₓ” in step S3006 of FIG. 3). The metal oxide layer 190 is formed by the sputtering method. Oxygen is implanted into the gate insulating layer 150 by the deposition of the metal oxide layer 190.

For example, a thickness of the metal oxide layer 190 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 190. Aluminum oxide has a high barrier property against gas. In the present embodiment, the aluminum oxide used as the metal oxide layer 190 suppresses the oxygen implanted into the gate insulating layer 150 at the time of the deposition of the metal oxide layer 190 from diffusing outward.

For example, in the case where the metal oxide layer 190 is formed by the sputtering method, a process gas used in the sputtering remains in the film of the metal oxide layer 190. For example, in the case where Ar is used as the process gas for sputtering, Ar may remain in the film of the metal oxide layer 190. The remaining Ar can be detected by a SIMS (Secondary Ion Mass Spectrometry) analyses on the metal oxide layer 190.

Heat treatment (oxidation anneal) for supplying oxygen to the oxide semiconductor layer 140 is performed in a state where the gate insulating layer 150 is deposited on the oxide semiconductor layer 140 and the metal oxide layer 190 is deposited on the gate insulating layer 150 (“Annealing for Oxidation” in step S3007 of FIG. 3). In the process from the deposition of the oxide semiconductor layer 140 to the deposition of the gate insulating layer 150 on the oxide semiconductor layer 140, a large amount of oxygen deficiencies occur in the upper surface 141 and the side surface 143 of the oxide semiconductor layer 140. Oxygen released from the gate insulating layers 120 and 150 is supplied to the oxide semiconductor layer 140 by the above-described oxidation anneal, and the oxygen deficiencies are repaired.

In the oxidation anneal described above, the oxygen implanted into the gate insulating layer 150 is blocked by the metal oxide layer 190. Therefore, discharge of the oxygen to the atmosphere is suppressed. As a result, the oxygen is efficiently supplied to the oxide semiconductor layer 140 by the oxidation anneal, and the oxygen deficiencies are repaired.

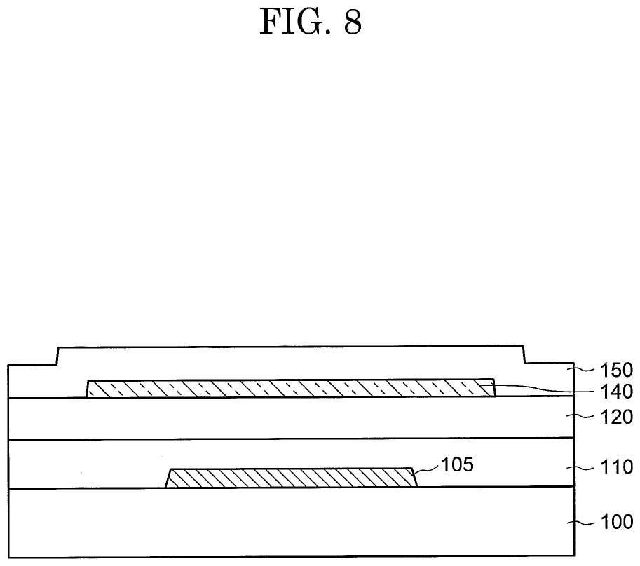

As shown in FIG. 3 and FIG. 8, the metal oxide layer 190 is etched (removed) after the oxidation anneal (“Removing AlOₓ” in step S3008 of FIG. 3). Wet etching may be used, or dry etching may be used as the etching of the metal oxide layer 190. For example, dilute hydrofluoric acid (DHF) is used for the wet etching. The metal oxide layer 190 formed on the entire surface is removed by the etching. In other words, the removal of the metal oxide layer 190 is performed without using a mask. In other words, all of the oxide layer 190 in a region overlapping the oxide semiconductor layer 140 formed in one pattern is removed in at least a plan view by the etching.

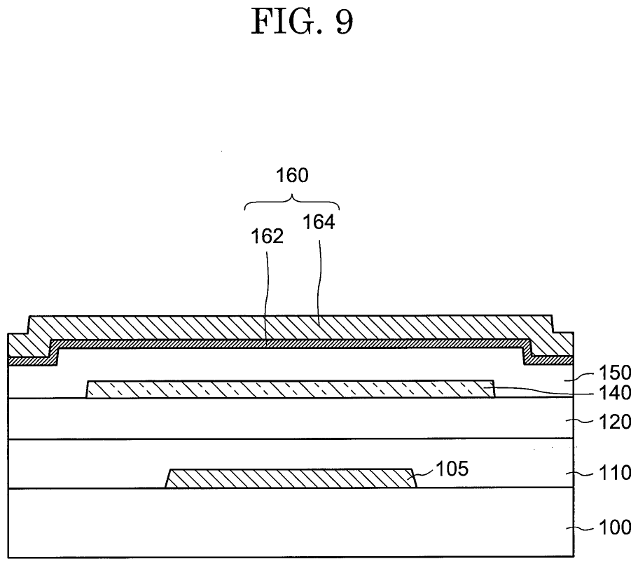

Next, the gate electrode 160 is formed on the gate insulating layer 150 (“Forming GE” in step S3009 of FIG. 3). As shown in FIG. 9, the titanium-containing layer 162 and the conductive layer 164 are deposited in sequence. The titanium-containing layer 162 and the conductive layer 164 are deposited by sputtering or an atomic layer deposition method for the gate electrode 160. In this embodiment, as mentioned above, the gate electrode 160 should use a stacked structure of the titanium-containing layer 162 and the conductive layer 164. In this embodiment, the thickness of the titanium-containing layer 162 is 25 nm or more and 50 nm or less. The thickness of the conductive layer 164 is 100 nm or more and 400 nm or less.

When the titanium-containing layer 162 is a stacked structure of a titanium layer and a nitrogen-containing titanium layer with nitrogen added to the titanium layer, nitrogen may be implanted into the titanium layer using an ion implanter. Alternatively, the nitrogen-containing titanium layer may be formed by using nitrogen gas when depositing the titanium layer by sputtering. For example, within the thickness range of 25 nm or more and 50 nm or less of the titanium layer, a few nm from the surface may be a nitrogen-doped region.

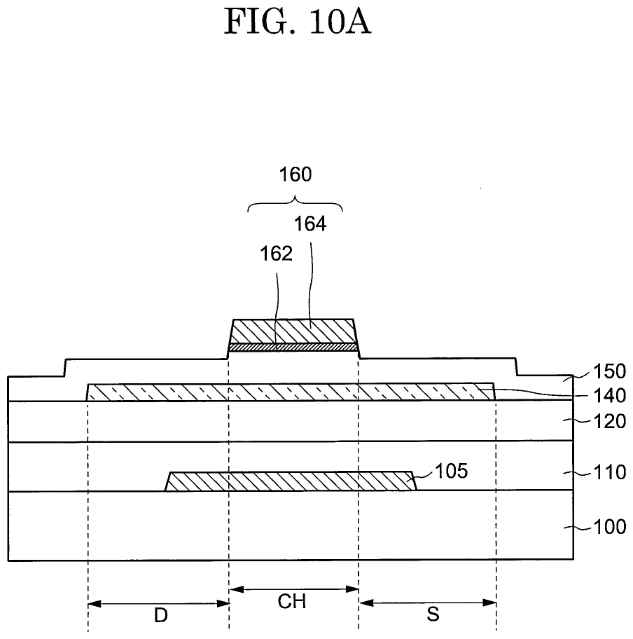

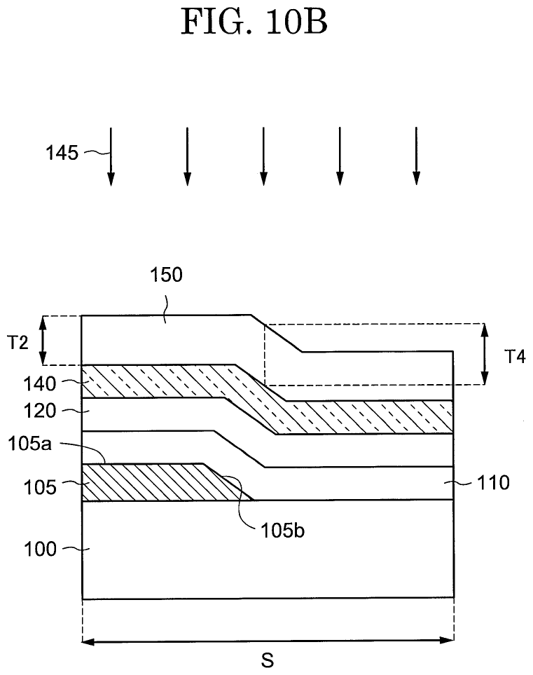

As shown in FIG. 10A, the titanium-containing layer 162 and the conductive layer 164 are patterned through a photolithography process. The titanium-containing layer 162 and the conductive layer 164 are processed by dry etching. An etching rate of the titanium-containing layer 162 is slower than that of the conductive layer 164. In this embodiment, a thickness of the titanium-containing layer 162 is 25 nm or more and 50 nm or less. Therefore, the in-plane variation of a line width of the gate electrode 160 within the substrate plane can be suppressed. In addition, in the second region 154 of the gate insulating layer 150, the in-plane variation of the amount removed can be suppressed. By dry etching, the thickness T2 of the second region 154 is 75 nm or more and 100 nm or less. Considering a relationship between the thickness T3 of the titanium-containing layer 162 and the thickness of the gate insulating layer 150, the thickness T3 of the titanium-containing layer 162 should be 25% or more and 70% or less of the thickness T2 of the second region 154. As described above, the gate electrode 160 is formed in contact with the gate insulating layer 150 exposed by the removal of the metal oxide layer 190.

Resistances of the source region S and the drain region D of the oxide semiconductor layer 140 are reduced (“Reducing resistance of SD” in step S3010 of FIG. 3) in a state where the gate electrode 160 is patterned. Specifically, impurities are implanted into the oxide semiconductor layer 140 from the gate electrode 160 side via the gate insulating layer 150 by ion implantation. For example, argon (Ar), phosphorus (P), and boron (B) are implanted into the oxide semiconductor layer 140 by the ion implantation. Oxygen deficiencies are formed in the oxide semiconductor layer 140 by the ion implantation, thereby reducing the resistance of the oxide semiconductor layer 140. Since the gate electrode 160 is arranged above the oxide semiconductor layer 140 functioning as the channel region CH of the semiconductor device 10, impurities are not implanted into the oxide semiconductor layer 140 in the channel region CH.

In this embodiment, the thickness T2 of the second region 154 of the gate insulating layer 150 is formed to 75 nm or more and 100 nm or less. Within this range, impurities can be added uniformly within the substrate surface to satisfy the conditions for acceleration of the ion implanter. When the thickness T2 of the second region 154 exceeds 100 nm, it is equivalent to an effective increase in the thickness of the gate insulating layer 150 in the region where the oxide semiconductor layer 140 overlaps a tapered portion of the gate electrode 105.

FIG. 10B is an enlarged magnified view of a portion of the semiconductor device shown in FIG. 10A. Specifically, FIG. 10B is an enlarged view of the region around the gate electrode 105. The gate electrode 105 includes a top surface 105a and a tapered portion 105b. In a region where the oxide semiconductor layer 140 overlaps on the top surface 105a of the gate electrode 105 and in a region where the gate electrode 105 is not provided, the thickness of the second region 154 is the thickness T2. However, in the region where the oxide semiconductor layer 140 overlaps on the tapered portion 105b, the thickness becomes a thickness T4 which is thicker than the thickness T2. When an impurity 145 is added by ion implantation in such a state, if the thickness T4 is 125 nm or less, the impurity 145 can be added uniformly to the source region S and the drain region D of the oxide semiconductor layer 140. When the thickness T4 exceeds 125 nm, the conditions for acceleration of the ion implanter may not be met. In the region overlapping the tapered portion 105b of the oxide semiconductor layer 140, the impurity 145 may not be sufficiently added. This may cause the resistance of the source region S and the drain region D to be non-uniform within the substrate plane. This tendency becomes more pronounced when there is in-plane variation in the amount of gate insulating layer 150 removed during dry etching of the gate electrode 160.

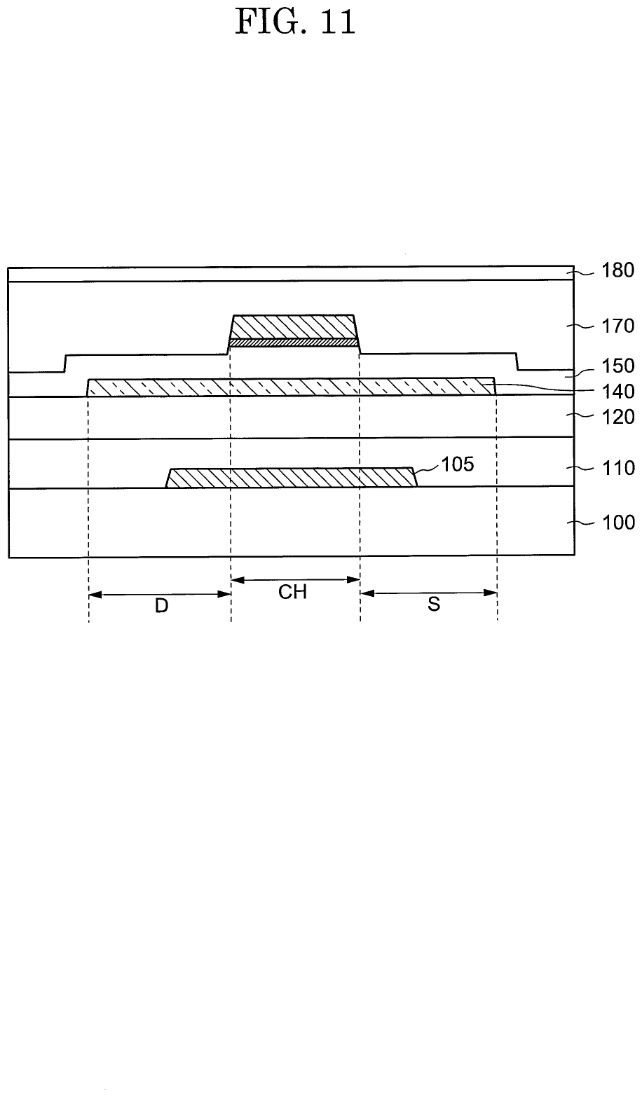

As shown in FIG. 3 and FIG. 11, the insulating layers 170 and 180 are deposited on the gate insulating layer 150 and the gate electrode 160 as interlayer films (“Depositing Interlayer film” in step S3011 of FIG. 3). The insulating layers 170 and 180 are deposited by the CVD method. For example, silicon nitride is formed as the insulating layer 170, and silicon oxide is formed as the insulating layer 180. The materials used as the insulating layers 170 and 180 are not limited to the above. A thickness of the insulating layer 170 is 50 nm or more and 500 nm or less. A thickness of the insulating layer 180 is 50 nm or more and 500 nm or less.

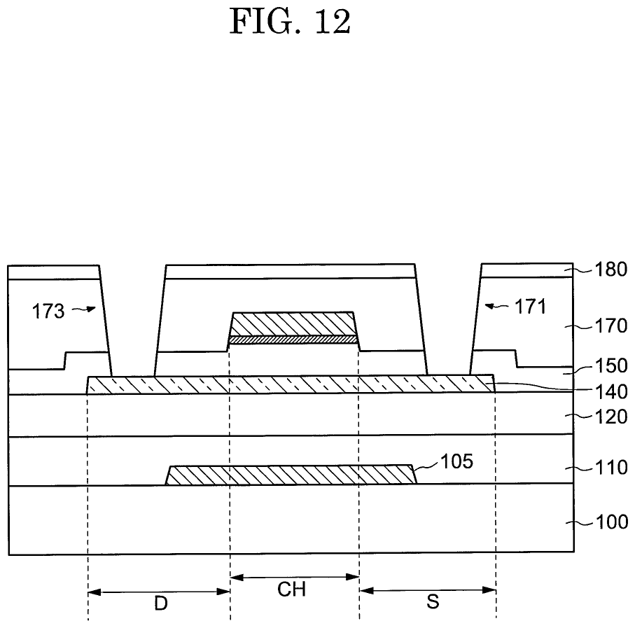

As shown in FIG. 3 and FIG. 12, the openings 171 and 173 are formed in the gate insulating layer 150 and the insulating layers 170 and 180 (“Opening Contact Hole” in step S3012 of FIG. 3). The oxide semiconductor layer 140 in the source region S is exposed by the opening 171. The oxide semiconductor layer 140 in the drain region D is exposed by the opening 173. The semiconductor device 10 shown in FIG. 1A is completed by forming the source-drain electrode 200 on the oxide semiconductor layer 140 exposed by the openings 171 and 173 and on the insulating layer 180 (“Forming SD” in step S3013 of FIG. 3).

With respect to the semiconductor device 10 manufactured by the above-described manufacturing method, it is possible to obtain electrical characteristics having a mobility of 30 [cm²/Vs] or more, 35 [cm²/Vs] or more, or 40 [cm²/Vs] or more in the range where the channel length L of the channel region CH is 2 μm or more and 4 μm or less and the channel width of the channel region CH is 2 μm or more and 25 μm or less. The mobility in the present embodiment is the field-effect mobility in a saturation region in the electrical characteristics of the semiconductor device 10. Specifically, the mobility means the largest value of the field-effect mobility in a region where a potential difference (Vd) between the source electrode and the drain electrode is greater than a value (Vg−Vth) obtained by subtracting a threshold-voltage (Vth) of the semiconductor device 10 from a voltage (Vg) supplied to the gate electrode.

In this embodiment, after the deposition of the gate insulating layer 150, an oxide metal layer 190 is deposited and oxidation annealing is performed. By the oxidation annealing, the oxygen is efficiently supplied to the oxide semiconductor layer 140, and the oxygen defects can be sufficiently repaired. Therefore, even if the thickness T1 of the first region 152 of the gate insulating layer 150 is 100 nm or more and 125 nm or less and the thickness T2 of the second region 154 is 75 nm or more and 100 nm or less, the electrical characteristics of the transistor can be prevented from becoming normally-on.

### Second Embodiment

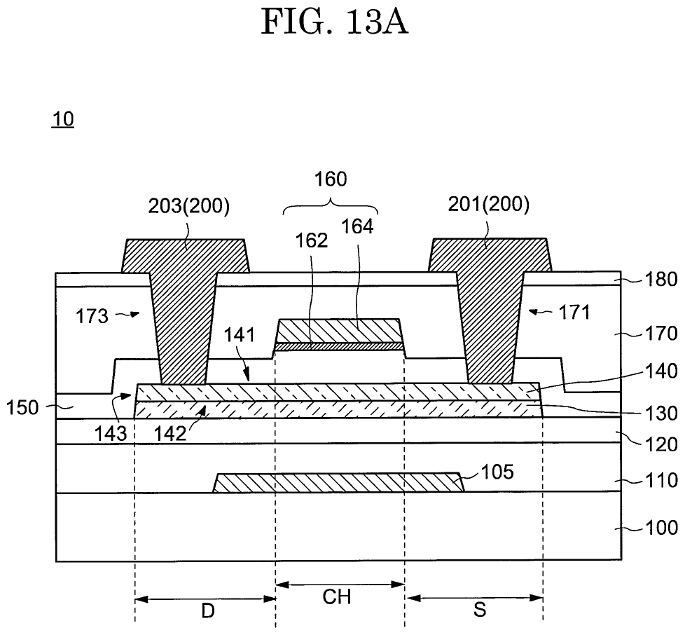

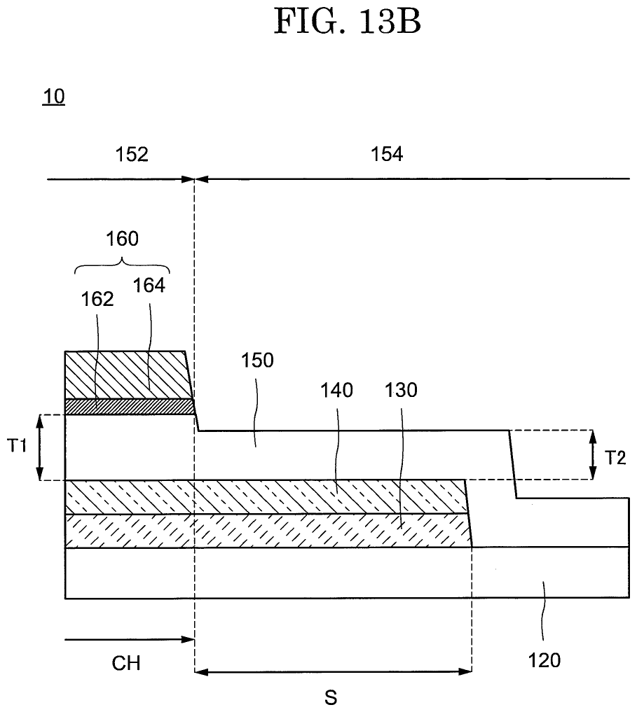

A semiconductor device according to an embodiment of the present invention will be described with reference to FIG. 13A to FIG. 24.

### [Configuration of Semiconductor Device 10]

A configuration of the semiconductor device 10 according to the present embodiment is similar to that of the semiconductor device 10 of the first embodiment but the embodiment is different from the configuration of the semiconductor device 10 of the first embodiment in that a metal oxide layer 130 is arranged between the gate insulating layer 120 and the oxide semiconductor layer 140. In the following description, the same configurations as those of the first embodiment will be omitted, and differences from the first embodiment will be mainly described.

FIG. 13A is a cross-sectional view showing an outline of a semiconductor device according to an embodiment of the present invention. FIG. 13B is an enlarged magnified view of a portion of the semiconductor device shown in FIG. 13A. As shown in FIG. 13A, the semiconductor device 10 includes the gate electrode 105, the gate insulating layers 110 and 120, the metal oxide layer 130, the oxide semiconductor layer 140, the gate insulating layer 150, the gate electrode 160, the insulating layers 170 and 180, the source electrode 201, and the drain electrode 203.

The metal oxide layer 130 is arranged above the gate insulating layer 120. The metal oxide layer 130 is in contact with the gate insulating layer 120. The oxide semiconductor layer 140 is arranged above the metal oxide layer 130. The oxide semiconductor layer 140 is in contact with the metal oxide layer 130. Among the main surface of the oxide semiconductor layer 140, a surface in contact with the metal oxide layer 130 is referred to as a lower surface 142. An end portion of the metal oxide layer 130 substantially coincides with an end portion of the oxide semiconductor layer 140.

In the present embodiment, no semiconductor layer or oxide semiconductor layer is arranged between the metal oxide layer 130 and the substrate 100.

In this embodiment, a metal oxide layer is provided in contact with a bottom of the oxide semiconductor layer 140. In FIG. 13A and FIG. 13B, although a configuration in which the metal oxide layer 130 is in contact with the gate insulating layer 120 and the oxide semiconductor layer 140 is in contact with the metal oxide layer 130 is exemplified, the configuration is not limited to this configuration. Other layers may be arranged between the gate insulating layer 120 and the metal oxide layer 130. Other layers may be arranged between the metal oxide layer 130 and the oxide semiconductor layer 140.

In FIG. 13A, although sidewalls of the metal oxide layer 130 and sidewalls of the oxide semiconductor layer 140 are arranged in a straight line, the configuration is not limited to this configuration. An angle of the sidewall of the metal oxide layer 130 with respect to the main surface of the substrate 100 may be different from an angle of the sidewall of the oxide semiconductor layer 140 with respect to the main surface. The cross-sectional shapes of the side wall of at least one of the metal oxide layer 130 or the oxide semiconductor layer 140 may be curved.

The metal oxide layer 130 is a layer containing a metal oxide containing aluminum as the main component similar to the metal oxide layer 190, and has a gas barrier film for shielding a gas such as oxygen or hydrogen. The same material as the metal oxide layer 190 is used for the metal oxide layer 130. The material of the metal oxide layer 130 may be the same as or different from the metal oxide layer 190.

As shown in FIG. 13B, in the gate insulating layer 150, the thickness T1 of the first region 152 is different from the thickness T2 of the second region 154. The thickness T1 of the first region 152 is the thickness of the gate insulating layer 150 when it is deposited in the manufacturing process. The thickness T2 of the second region 154 is the thickness formed by dry etching when the gate electrode 160 is formed.

Since the planar shape of the semiconductor device 10 is the same as that of FIG. 2, the illustration thereof is omitted. However, the planar pattern of the metal oxide layer 130 is substantially the same as the planar pattern of the oxide semiconductor layer 140. Referring to FIG. 13A, the lower surface 142 of the oxide semiconductor layer 140 is covered with the metal oxide layer 130. In particular, in the present embodiment, all of the lower surface 142 of the oxide semiconductor layer 140 is covered with the metal oxide layer 130.

In the present embodiment, although a configuration in which all of the lower surface 142 of the oxide semiconductor layer 140 is covered with the metal oxide layer 130 is exemplified, the present invention is not limited to this configuration. For example, a part of the lower surface 142 of the oxide semiconductor layer 140 may not be in contact with the metal oxide layer 130. For example, all of the lower surface 142 of the oxide semiconductor layer 140 in the channel region CH may be covered with the metal oxide layer 130, and all or part of the lower surface 142 of the oxide semiconductor layer 140 in the source region S and the drain region D may not be covered with the metal oxide layer 130. That is, all or part of the lower surface 142 of the oxide semiconductor layer 140 in the source region S and the drain region D may not be in contact with the metal oxide layer 130. However, in the above configuration, a part of the lower surface 142 of the oxide semiconductor layer 140 in the channel region CH may not be covered with the metal oxide layer 130, and the other part of the lower surface 142 may be in contact with the metal oxide layer 130.

In the case where the ratio of indium in the oxide semiconductor layer 140 is 50% or more, the semiconductor device 10 with high mobility is realized. On the other hand, since the oxygen contained in the oxide semiconductor layer 140 is easily reduced in such an oxide semiconductor layer 140, oxygen deficiencies are easily formed in the oxide semiconductor layer 140.

In the semiconductor device 10, hydrogen is released from a layer (for example, the gate insulating layers 110 and 120) arranged closer to the substrate 100 side than the oxide semiconductor layer 140 in the heat treatment step of the manufacturing process. When the hydrogen reaches the oxide semiconductor layer 140, oxygen deficiencies occur in the oxide semiconductor layer 140. The occurrence of the oxygen deficiencies is more pronounced the larger the pattern size of the oxide semiconductor layer 140 becomes. In order to suppress the occurrence of such oxygen deficiencies, it is necessary to suppress hydrogen from reaching the lower surface 142 of the oxide semiconductor layer 140. This is the first problem.

The upper surface 141 of the oxide semiconductor layer 140 is affected by a process (for example, a patterning process or an etch process) after the oxide semiconductor layer 140 is formed. On the other hand, the lower surface 142 of the oxide semiconductor layer 140 (the surface of the oxide semiconductor layer 140 facing the substrate 100) is not affected as described above.

Therefore, there are more oxygen deficiencies formed near the upper surface 141 of the oxide semiconductor layer 140 than the oxygen deficiencies formed near the lower surface 142 of the oxide semiconductor layer 140. That is, the oxygen deficiencies in the oxide semiconductor layer 140 do not exist uniformly in a thickness direction of the oxide semiconductor layer 140, but exist in a non-uniform distribution in the thickness direction of the oxide semiconductor layer 140. Specifically, there are fewer oxygen deficiencies in the oxide semiconductor layer 140 toward the lower surface 142 side of the oxide semiconductor layer 140 and more oxygen deficiencies toward the upper surface 141 side of the oxide semiconductor layer 140.

In the case where an oxygen supply process is uniformly performed on the oxide semiconductor layer 140 having the oxygen deficiency distribution as described above, oxygen is excessively supplied to the lower surface 142 side of the oxide semiconductor layer 140 when supplying oxygen in an amount required to repair the oxygen deficiencies formed on the upper surface 141 side of the oxide semiconductor layer 140. As a result, a defect level different from the oxygen vacancies is formed on the lower surface 142 side due to the excess oxygen. As a result, phenomenon such as variation in characteristics in the reliability test or a decrease in field-effect mobility occurs. Therefore, in order to suppress such phenomenon, it is necessary to supply oxygen to the upper surface 141 side of the oxide semiconductor layer 140 while suppressing the oxygen supply to the lower surface 142 side of the oxide semiconductor layer 140.

The above problems are newly recognized in the process of reaching the present invention but are not problems that have been conventionally recognized. In the conventional configuration and manufacturing method, there was a trade-off relationship between the initial characteristics and the reliability test, in which the variation in characteristics according to the reliability test occurs even when the initial characteristics of the semiconductor device are improved by the oxygen supply process to the oxide semiconductor layer. However, with the configuration according to the present embodiment, the above problems are solved, and it is possible to obtain good initial characteristics and a reliability test result of the semiconductor device 10.

### [Method for Manufacturing Semiconductor Device 10]

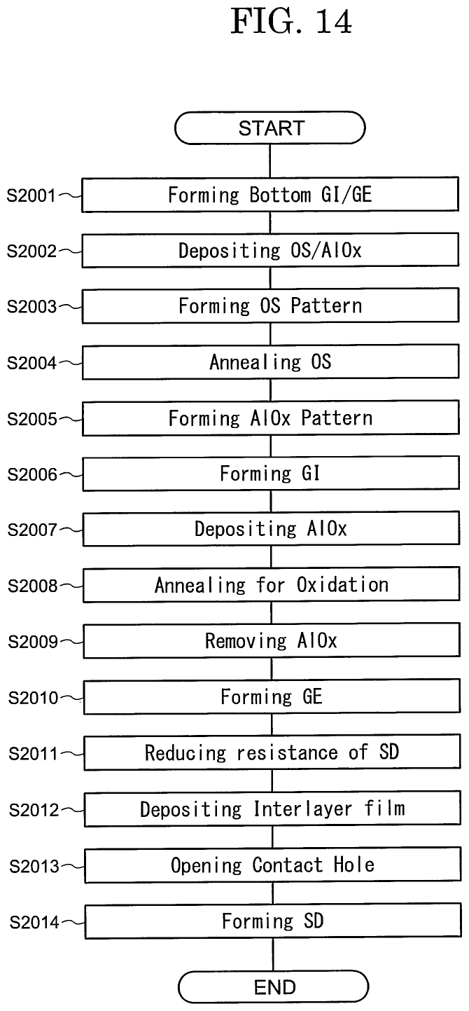

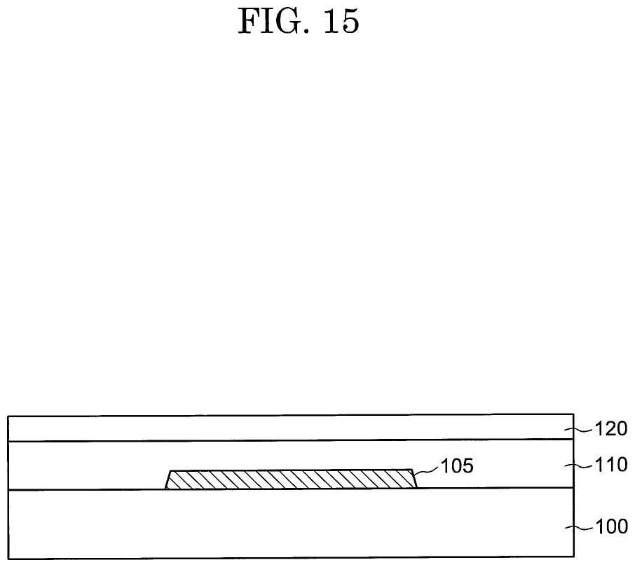

A method for manufacturing a semiconductor device according to an embodiment of the present invention will be described with reference to FIG. 14 to FIG. 24. FIG. 14 is a sequence diagram showing a method for manufacturing a semiconductor device according to an embodiment of the present invention. FIG. 15 to FIG. 24 are cross-sectional views showing a method for manufacturing a semiconductor device according to an embodiment of the present invention. In the description of the manufacturing method shown below, a method for manufacturing the semiconductor device 10 in which aluminum oxide is used as the metal oxide layers 130 and 190 will be described.

As shown in FIG. 14 and FIG. 15, the gate electrode 105 is formed on the substrate 100 as the bottom-gate, and the gate insulating layers 110 and 120 are formed on the gate electrode 105 (“Forming Bottom GI/GE” in step S2001 of FIG. 14). For example, silicon nitride is formed as the gate insulating layer 110. For example, silicon oxide is formed as the gate insulating layer 120. The gate insulating layers 110 and 120 are formed by a CVD (Chemical Vapor Deposition) method.

Using silicon nitride as the gate insulating layer 110 allows the gate insulating layer 110 to block impurities that diffuse, for example, from the substrate 100 toward the oxide semiconductor layer 140. The silicon oxide used as the gate insulating layer 120 is silicon oxide having a physical property of releasing oxygen by a heat treatment.

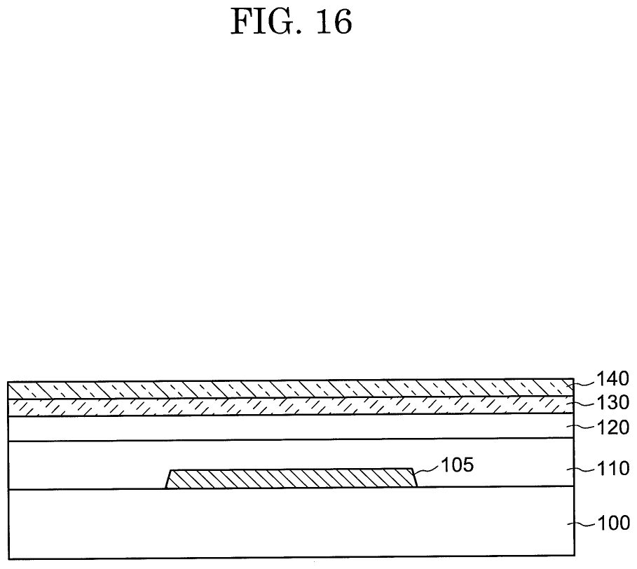

As shown in FIG. 14 and FIG. 16, the metal oxide layer 130 and the oxide semiconductor layer 140 are formed on the gate insulating layer 120 (“Depositing OS/AlOₓ” in step S2002 of FIG. 14). The metal oxide layer 130 and the oxide semiconductor layer 140 are deposited by a sputtering method or an atomic layer deposition method (ALD).

For example, a thickness of the metal oxide layer 130 is 1 nm or more and 100 nm or less, 1 nm or more and 50 nm or less, 1 nm or more and 30 nm or less, or 1 nm or more and 10 nm or less. In the present embodiment, aluminum oxide is used as the metal oxide layer 130. Aluminum oxide has a high barrier property against gas. In the present embodiment, the aluminum oxide used as the metal oxide layer 130 blocks hydrogen and oxygen released from the gate insulating layer 120, and suppresses the released hydrogen and oxygen from reaching the oxide semiconductor layer 140.

For example, a thickness of the oxide semiconductor layer 140 is 10 nm or more and 100 nm or less, 15 nm or more and 70 nm or less, or 20 nm or more and 40 nm or less. In this embodiment, an oxide containing indium (In) and gallium (Ga) is used as the oxide semiconductor layer 140. The oxide semiconductor layer 140 is amorphous prior to an OS anneal described later.

When the oxide semiconductor layer 140 is crystallized by the OS anneal process described later, the oxide semiconductor layer 140 after the deposition and before the OS anneal is preferably in an amorphous state (a state in which there are less low crystalline components of the oxide semiconductor). That is, the deposition conditions of the oxide semiconductor layer 140 are preferred to be such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, microcrystals occur in the oxide semiconductor layer 140 immediately after the deposition process. The microcrystals inhibit crystallization by a subsequent OS anneal. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is 100° C. or less, 70° C. or less, 50° C. or less, or 30° C. or less. As described above, depositing the oxide semiconductor layer 140 while cooling the object to be deposited makes it possible to deposit the oxide semiconductor layer 140 with few crystalline components in a state immediately after the deposition.

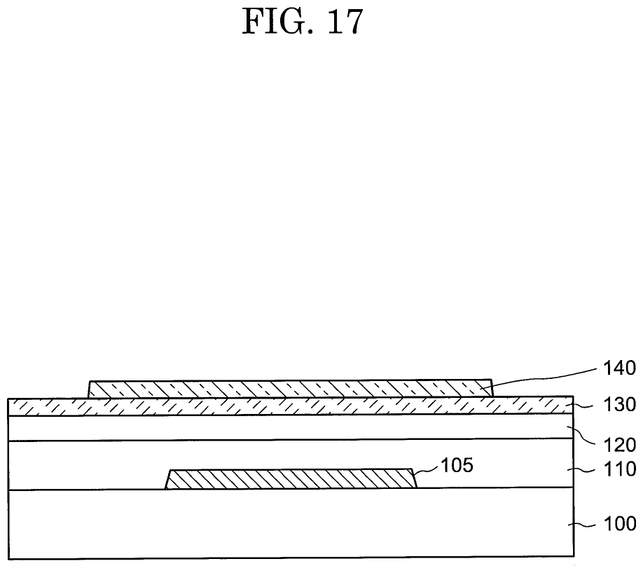

As shown in FIG. 14 and FIG. 17, a pattern of the oxide semiconductor layer 140 is formed (“Forming OS Pattern” in step S2003 of FIG. 14). Although not shown, a resist mask is formed on the oxide semiconductor layer 140, and the oxide semiconductor layer 140 is etched using the resist mask. Wet etching may be used, or dry etching may be used as the etching method of the oxide semiconductor layer 140. The wet etching may include etching using an acidic etchant. For example, oxalic acid or hydrofluoric acid may be used as the etchant.

A heat treatment (OS anneal) (“Annealing OS” in step S2004 of FIG. 14) is performed on the oxide semiconductor layer 140 after the pattern of the oxide semiconductor layer 140 is formed. In the present embodiment, the oxide semiconductor layer 140 is crystallized by the OS anneal.

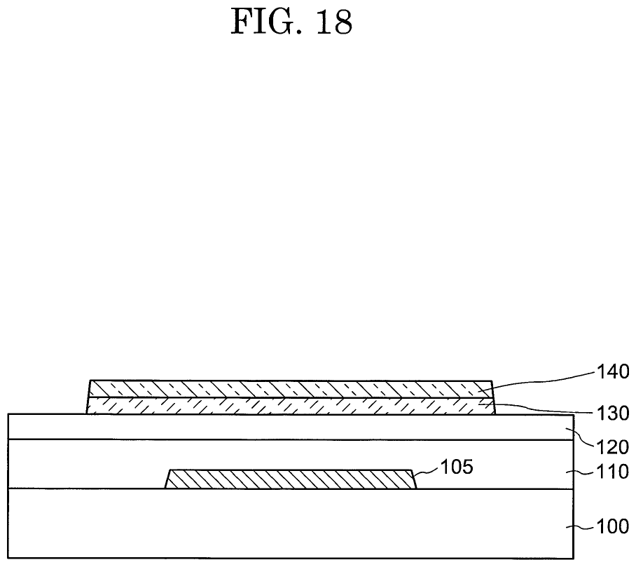

As shown in FIG. 14 and FIG. 18, a pattern of the metal oxide layer 130 is formed (“Forming AlOₓ Pattern” in step S2005 of FIG. 14). The metal oxide layer 130 is etched using the oxide semiconductor layer 140 patterned in the above process as a mask. Wet etching may be used, or dry etching may be used as the etching method of the metal oxide layer 130. For example, dilute hydrofluoric acid (DHF) is used for the wet etching. As described above, a photolithography process can be omitted by etching the metal oxide layer 130 using the oxide semiconductor layer 140 as the mask.

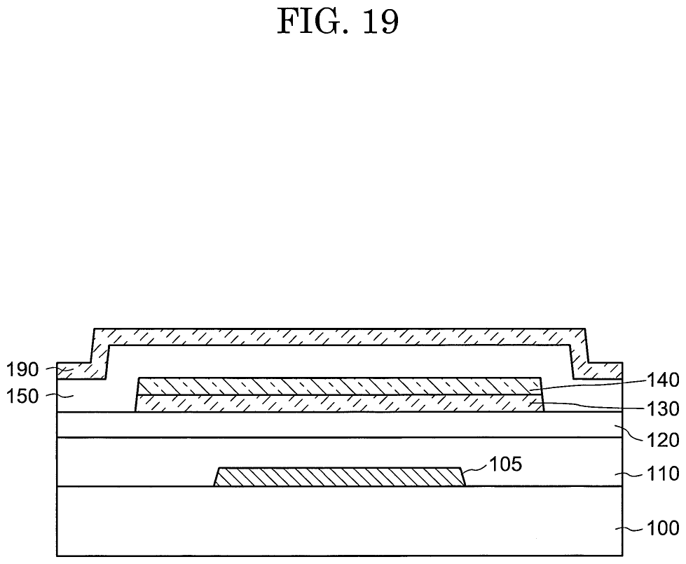

As shown in FIG. 14 and FIG. 19, the gate insulating layer 150 is deposited on the oxide semiconductor layer 140 (“Forming GI” in step S2006 of FIG. 14). For example, silicon oxide is formed as the gate insulating layer 150. The gate insulating layer 150 is formed by the CVD method. For example, the gate insulating layer 150 may be deposited at a deposition temperature of 350° C. or higher in order to form an insulating layer having few defects as described above as the gate insulating layer 150. For example, the thickness of the gate insulating layer 150 is 50 nm or more and 300 nm or less, 60 nm or more and 200 nm or less, or 70 nm or more and 150 nm or less. A process of implanting oxygen may be performed on a part of the gate insulating layer 150 after the gate insulating layer 150 is deposited. The metal oxide layer 190 is deposited on the gate insulating layer 150 (“Depositing AlOₓ” in step S2007 of FIG. 14). The metal oxide layer 190 is formed by the sputtering method. Oxygen is implanted into the gate insulating layer 150 by the deposition of the metal oxide layer 190.

For example, a thickness of the metal oxide layer 190 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 190. Aluminum oxide has a high barrier property against gas. In the present embodiment, the aluminum oxide used as the metal oxide layer 190 suppresses the oxygen implanted into the gate insulating layer 150 at the time of the deposition of the metal oxide layer 190 from diffusing outward.

For example, in the case where the metal oxide layer 190 is formed by the sputtering method, a process gas used in the sputtering remains in the film of the metal oxide layer 190. For example, in the case where Ar is used as the process gas for sputtering, Ar may remain in the film of the metal oxide layer 190. The remaining Ar can be detected by a SIMS (Secondary Ion Mass Spectrometry) analysis on the metal oxide layer 190.

A heat treatment (oxidation anneal) for supplying oxygen to the oxide semiconductor layer 140 is performed in a state where the gate insulating layer 150 is deposited on the oxide semiconductor layer 140 and the metal oxide layer 190 is deposited on the gate insulating layer 150 (“Annealing for Oxidation” in step S2008 of FIG. 14). In the process from the deposition of the oxide semiconductor layer 140 to the deposition of the gate insulating layer 150 on the oxide semiconductor layer 140, a large amount of oxygen deficiencies occur in the upper surface 141 and the side surface 143 of the oxide semiconductor layer 140. Oxygen released from the gate insulating layers 120 and 150 is supplied to the oxide semiconductor layer 140 by the above-described oxidation anneal, and the oxygen deficiencies are repaired.

Oxygen released from the gate insulating layer 120 by the oxidation anneal is blocked by the metal oxide layer 130. Therefore, oxygen is less likely to be supplied to the lower surface 142 of the oxide semiconductor layer 140. The oxygen released from the gate insulating layer 120 diffuses from a region where the metal oxide layer 130 is not formed to the gate insulating layer 150 arranged on the gate insulating layer 120 and reaches the oxide semiconductor layer 140 via the gate insulating layer 150. As a result, the oxygen released from the gate insulating layer 120 is less likely to be supplied to the lower surface 142 of the oxide semiconductor layer 140, and is mainly supplied to the side surface 143 and the upper surface 141 of the oxide semiconductor layer 140. Further, the oxidation anneal makes it possible to supply oxygen released from the gate insulating layer 150 to the upper surface 141 and the side surface 143 of the oxide semiconductor layer 140. The oxidation anneal may release hydrogen from the gate insulating layers 110 and 120 but the hydrogen is blocked by the metal oxide layer 130.

As described above, in the oxidation anneal step, it is possible to supply oxygen to the upper surface 141 and the side surface 143 of the oxide semiconductor layer 140 having a large amount of oxygen deficiencies while suppressing the supply of oxygen to the lower surface 142 of the oxide semiconductor layer 140 having a small amount of oxygen deficiencies.

Similarly, in the oxidation anneal step described above, the oxygen implanted into the gate insulating layer 150 is blocked by the metal oxide layer 190. Therefore, discharge of the oxygen to the atmosphere is suppressed. As a result, the oxygen is efficiently supplied to the oxide semiconductor layer 140 by the oxidation anneal, and the oxygen deficiencies are repaired.

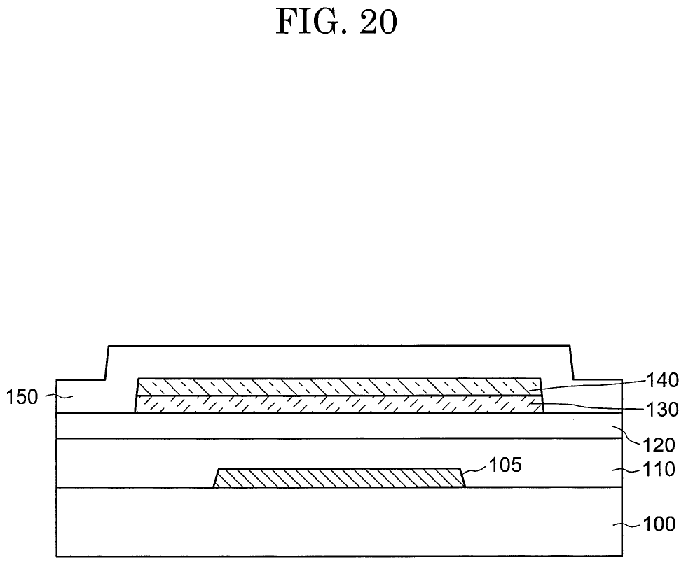

As shown in FIG. 14 and FIG. 20, the metal oxide layer 190 is etched (removed) after the oxidation anneal (“Removing AlOₓ” in step S2009 of FIG. 14). Wet etching may be used, or dry etching may be used as the etching method of the metal oxide layer 190. For example, dilute hydrofluoric acid (DHF) is used for the wet etching.

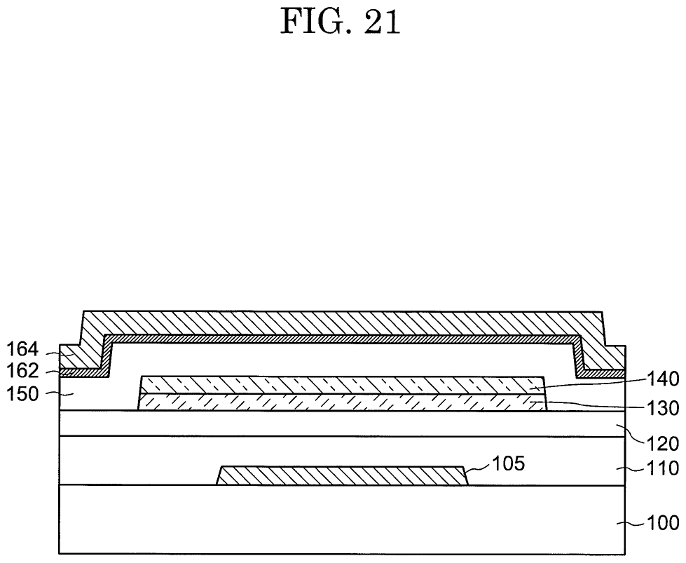

The gate electrode 160 is formed on the gate insulating layer 150 (“Forming GE” in step S2010 of FIG. 14). As shown in FIG. 21, the titanium-containing layer 162 and the conductive layer 164 are deposited in sequence. The titanium-containing layer 162 and the conductive layer 164 are deposited by the sputtering method or the atomic layer deposition method. In this embodiment, as described above, the gate electrode 160 may use a stacked structure of the titanium-containing layer 162 and the conductive layer 164. In this embodiment, a thickness of the titanium-containing layer 162 is 25 nm or more and 50 nm or less.

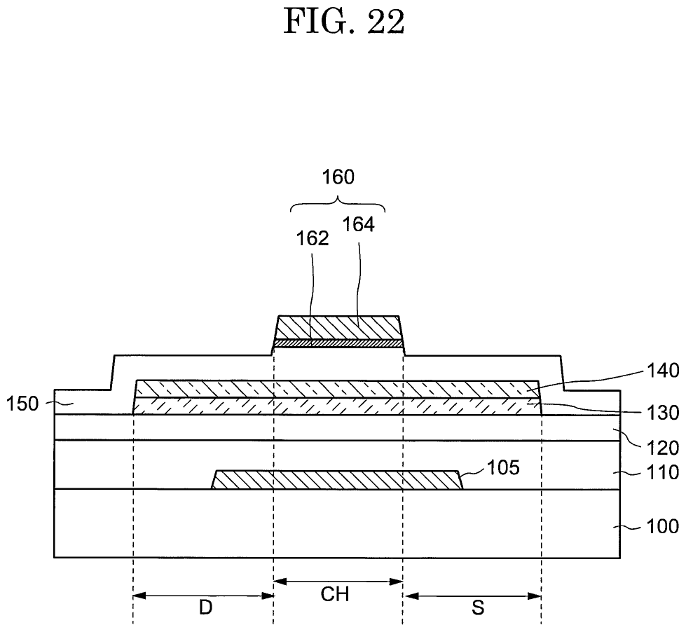

As shown in FIG. 22, the titanium-containing layer 162 and the conductive layer 164 are patterned through a photolithography process. The titanium-containing layer 162 and the conductive layer 164 are processed by dry etching. The etching rate of the titanium-containing layer 162 is slower than that of the conductive layer 164. In this embodiment, the thickness of the titanium-containing layer 162 is 25 nm or more and 50 nm or less. Therefore, the in-plane variation of a line width of the gate electrode 160 within the substrate plane can be suppressed. In addition, in the second region 154 of the gate insulating layer 150, the in-plane variation of the amount removed can be suppressed. By dry etching, the thickness T2 of the second region 154 is 75 nm or more and 100 nm or less. As described above, the gate electrode 160 is formed in contact with the gate insulating layer 150 exposed by the removal of the metal oxide layer 190.

Resistances of the source region S and the drain region D of the oxide semiconductor layer 140 are reduced (“Reducing resistance of SD” in step S2011 of FIG. 14) in a state where the gate electrode 160 is patterned. Specifically, impurities are implanted into the oxide semiconductor layer 140 from the gate electrode 160 side via the gate insulating layer 150 by ion implantation. For example, argon (Ar), phosphorus (P), or boron (B) are implanted into the oxide semiconductor layer 140 by the ion implantation. Oxygen deficiencies are formed in the oxide semiconductor layer 140 by the ion implantation, thereby reducing the resistance of the oxide semiconductor layer 140. Since the gate electrode 160 is arranged above the oxide semiconductor layer 140 functioning as the channel region CH of the semiconductor device 10, impurities are not implanted into the oxide semiconductor layer 140 in the channel region CH.

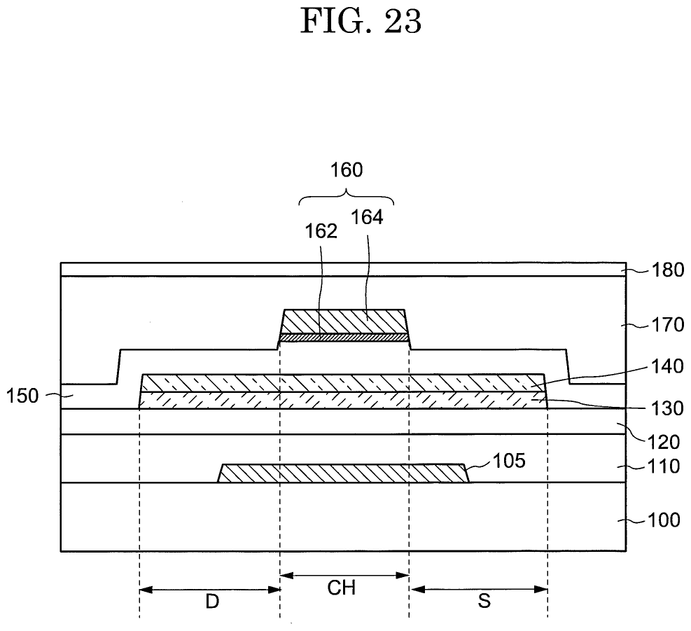

As shown in FIG. 14 and FIG. 23, the insulating layers 170 and 180 are deposited on the gate insulating layer 150 and the gate electrode 160 as interlayer films (“Depositing Interlayer film” in step S2012 of FIG. 14). The insulating layers 170 and 180 are deposited by the CVD method. For example, silicon nitride is formed as the insulating layer 170, and silicon oxide is formed as the insulating layer 180. The materials used as the insulating layers 170 and 180 are not limited to the above. A thickness of the insulating layer 170 is 50 nm or more and 500 nm or less. A thickness of the insulating layer 180 is 50 nm or more and 500 nm or less.

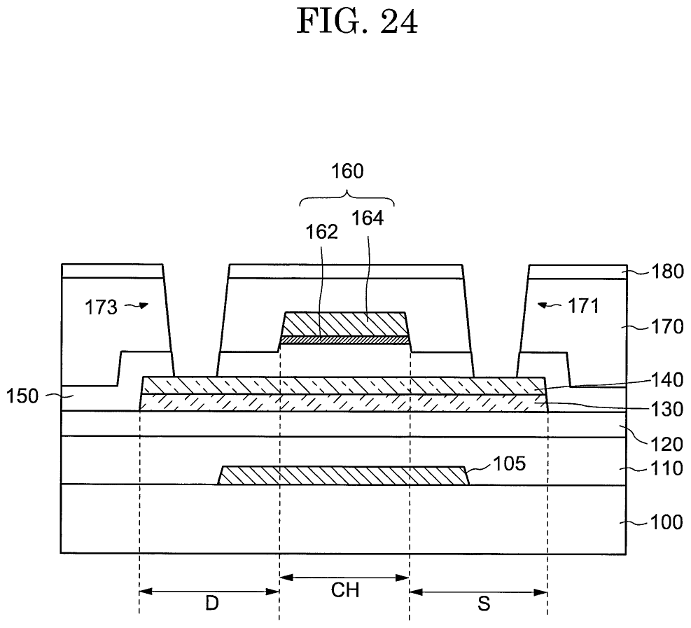

As shown in FIG. 14 and FIG. 24, the openings 171 and 173 are formed in the gate insulating layer 150 and the insulating layers 170 and 180 (“Opening Contact Hole” in step S2013 of FIG. 14). The oxide semiconductor layer 140 in the source region S is exposed by the opening 171. The oxide semiconductor layer 140 in the drain region D is exposed by the opening 173. The semiconductor device 10 shown in FIG. 13A is completed by forming the source-drain electrode 200 on the oxide semiconductor layer 140 exposed by the openings 171 and 173 and on the insulating layer 180 (“Forming SD” in step S2014 of FIG. 14).

With respect to the semiconductor device 10 manufactured by the above-described manufacturing method, it is possible to obtain electrical characteristics having a mobility of 50 [cm²/Vs] or more, 55 [cm²/Vs] or more, or 60 [cm²/Vs] or more in a range where the channel length L of the channel region CH is 2 μm or more and 4 μm or less and the channel width of the channel region CH is 2 μm or more and 25 μm or less. The mobility in the present embodiment is the field-effect mobility in a saturation region in the electrical characteristics of the semiconductor device 10. Specifically, the mobility means the largest value of the field-effect mobility in an region where a potential difference (Vd) between the source electrode and the drain electrode is greater than a value (Vg−Vth) obtained by subtracting a threshold-voltage (Vth) of the semiconductor device 10 from a voltage (Vg) supplied to the gate electrode.

### Third Embodiment

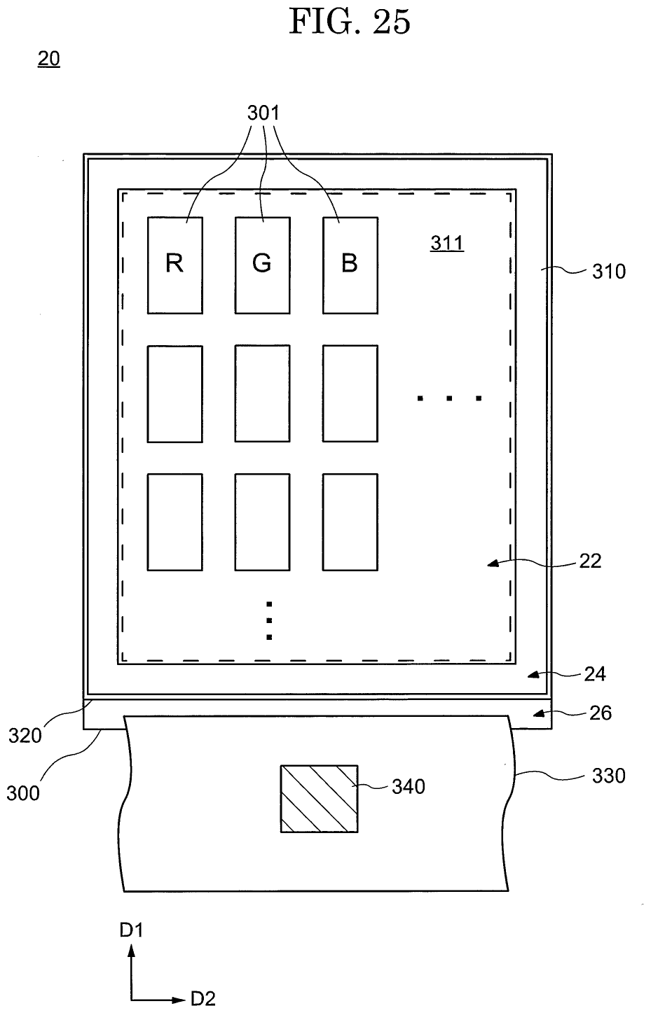

A display device using a semiconductor device according to an embodiment of the present invention will be described with reference to FIG. 25 to FIG. 29. In the embodiment shown below, configurations in which the semiconductor devices 10 described in the first embodiment and the second embodiment described above are applied to the circuit of the liquid crystal display device will be described.

### [Outline of Display Device 20]

FIG. 25 is a plan view showing an outline of a display device according to an embodiment of the present invention. As is shown in FIG. 25, the display device 20 includes an array substrate 300, a seal portion 310, a counter substrate 320, a flexible printed circuit substrate 330 (FPC 330), and an IC chip 340. The array substrate 300 and the counter substrate 320 are bonded together by the seal portion 310. A plurality of pixel circuits 301 is arranged in a matrix in a liquid crystal region 22 surrounded by the seal portion 310. The liquid crystal region 22 is a region overlapping a liquid crystal element 311, which will be described later, in a plan view.

A seal region 24 where the seal portion 310 is arranged is a region surrounding the liquid crystal region 22. The FPC 330 is arranged in a terminal region 26. The terminal region 26 is a region where the array substrate 300 is exposed from the counter substrate 320 and is arranged outside the seal region 24. Outside the seal region 24 means regions outside the region where the seal portion 310 is arranged and the region surrounded by the seal portion 310. The IC chip 340 is arranged on the FPC 330. The IC chip 340 supplies a signal for driving each pixel circuit 301.

### [Circuit Configuration of Display Device 20]

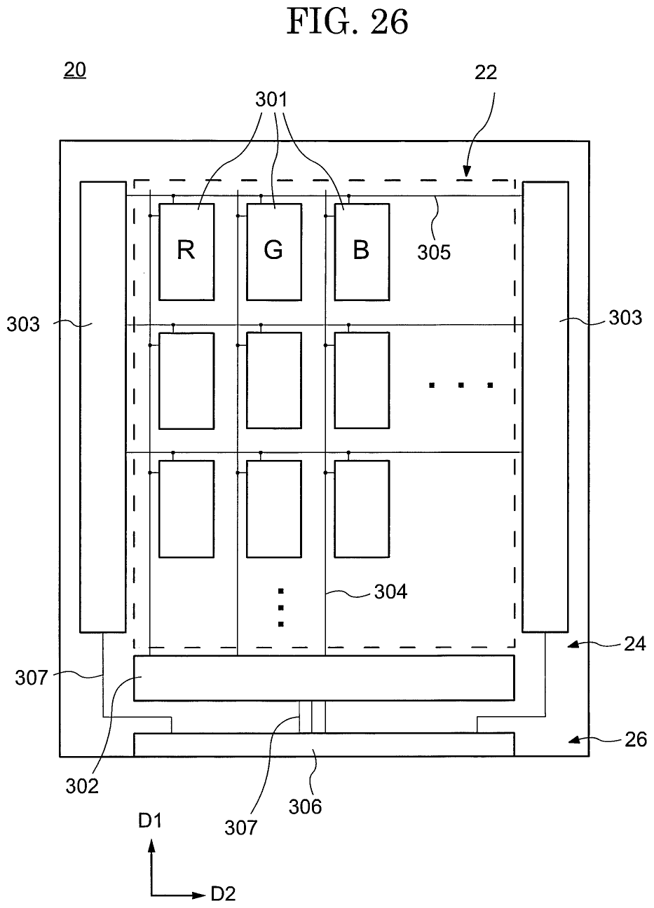

FIG. 26 is a block diagram showing a circuit configuration of a display device according to an embodiment of the present invention. As is shown in FIG. 26, a source driver circuit 302 is arranged at a position adjacent to the liquid crystal region 22 where the pixel circuit 301 is arranged in the direction D1 (column direction), and a gate driver circuit 303 is arranged at a position adjacent to the liquid crystal region 22 in the direction D2 (row direction). The source driver circuit 302 and the gate driver circuit 303 are arranged in the seal region 24 described above. However, the region where the source driver circuit 302 and the gate driver circuit 303 are arranged is not limited to the seal region 24. The source driver circuit 302 and the gate driver circuit 303 may be arranged in any region outside the region where the pixel circuit 301 is arranged.

A source wiring 304 extends from the source driver circuit 302 in the direction D1 and is connected to the plurality of pixel circuits 301 arranged in the direction D1. A gate wiring 305 extends from the gate driver circuit 303 in the direction D2 and is connected to the plurality of pixel circuits 301 arranged in the direction D2.

A terminal portion 306 is arranged in the terminal region 26. The terminal portion 306 and the source driver circuit 302 are connected by a connection wiring 307. Similarly, the terminal portion 306 and the gate driver circuit 303 are connected by the connection wiring 307. By connecting the FPC 330 to the terminal portion 306, an external device which is connected to the FPC 330 and the display device 20 are connected, and a signal from the external device drives each pixel circuit 301 arranged in the display device 20.

The semiconductor devices 10 shown in the first embodiment and the second embodiment are used as a transistor included in the pixel circuit 301, the source driver circuit 302, and the gate driver circuit 303.

### [Pixel Circuit 301 of Display Device 20]

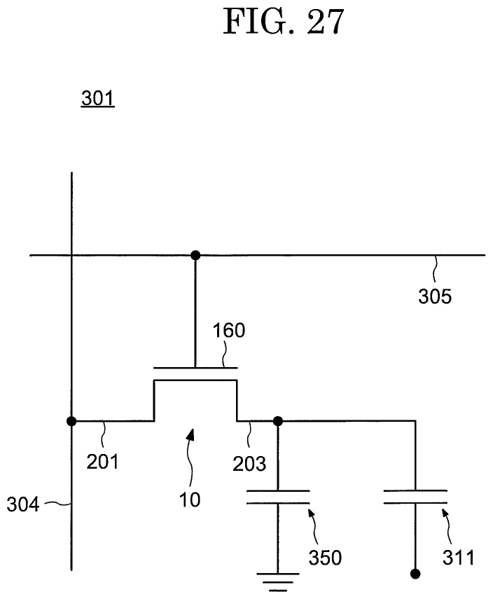

FIG. 27 is a circuit diagram showing a pixel circuit of a display device according to an embodiment of the present invention. As is shown in FIG. 27, the pixel circuit 301 includes elements such as the semiconductor device 10, a storage capacitor 350, and the liquid crystal element 311. The semiconductor device 10 has the gate electrode 160, the source electrode 201, and the drain electrode 203. The gate electrode 160 is connected to the gate wiring 305. The source electrode 201 is connected to the source wiring 304. The drain electrode 203 is connected to the storage capacitor 350 and the liquid crystal element 311. In the present embodiment, although an electrode indicated by 201 is referred to as a source electrode and an electrode indicated by 203 is referred to as a drain electrode for the convenience of explanation, the electrode indicated by 201 may function as a drain electrode and the electrode indicated by 203 may function as a source electrode.

### [Cross-Section of Display Device 20]

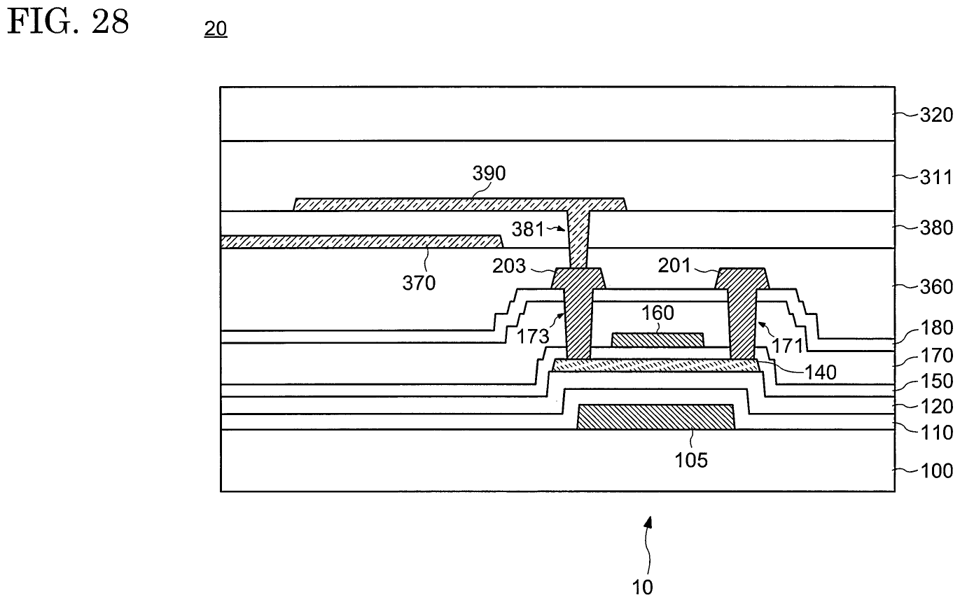

FIG. 28 is a cross-sectional view of a display device according to an embodiment of the present invention. As shown in FIG. 28, the display device 20 is a display device in which the semiconductor device 10 is used. In the present embodiment, although a configuration in which the semiconductor device 10 is used for the pixel circuit 301 is exemplified, the semiconductor device 10 may be used for a peripheral circuit including the source driver circuit 302 and the gate driver circuit 303. In the following description, since the configuration of the semiconductor device 10 is the same as that of the semiconductor device 10 shown in FIG. 1A, the description thereof will be omitted.

An insulating layer 360 is arranged on the source electrode 201 and the drain electrode 203. A common electrode 370 arranged in common for the plurality of pixels is arranged on the insulating layer 360. An insulating layer 380 is arranged on the common electrode 370. An opening 381 is arranged in the insulating layers 360 and 380. A pixel electrode 390 is arranged on the insulating layer 380 and within the opening 381. The pixel electrode 390 is connected to the drain electrode 203.

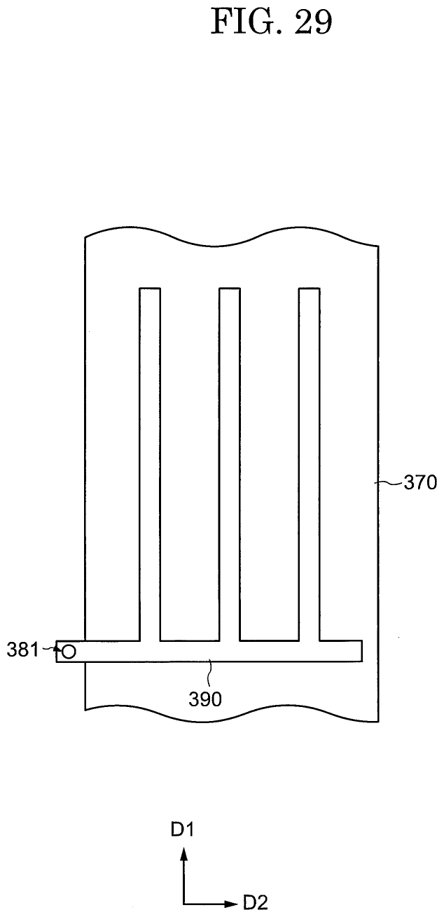

FIG. 29 is a plan view of a pixel electrode and a common electrode of a display device according to an embodiment of the present invention. As shown in FIG. 29, the common electrode 370 has an overlapping region overlapping the pixel electrode 390 in a plan view, and a non-overlapping region not overlapping the pixel electrode 390. When a voltage is supplied between the pixel electrode 390 and the common electrode 370, a horizontal electric field is formed from the pixel electrode 390 in the overlapping region toward the common electrode 370 in the non-overlapping region. The gradation of the pixel is determined by the operation of liquid crystal molecules included in the liquid crystal element 311 by the horizontal electric field.

### Fourth Embodiment

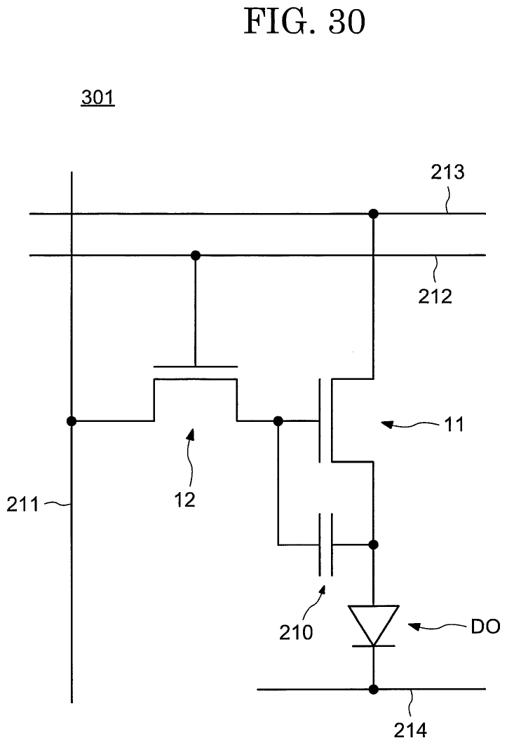

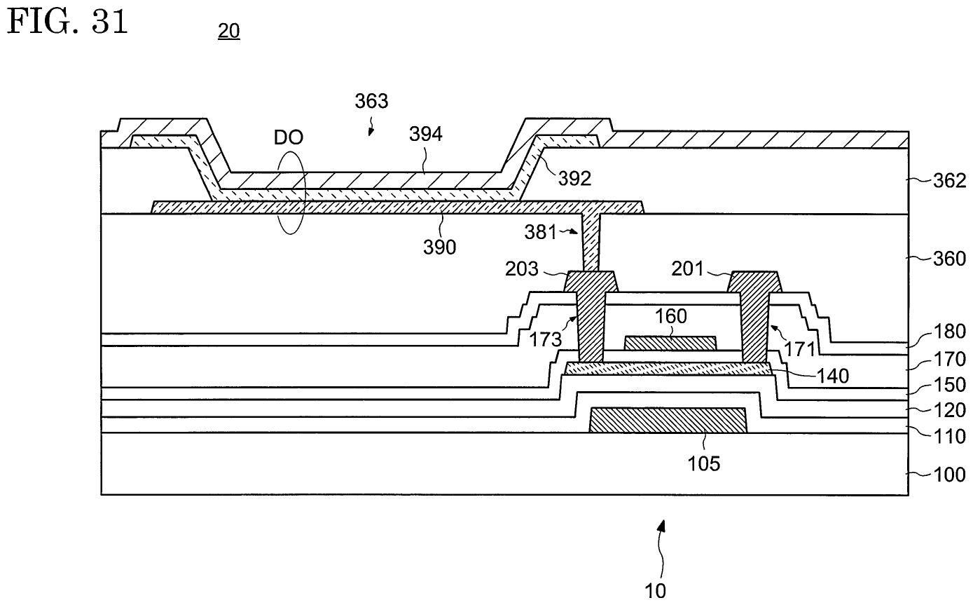

A display device using a semiconductor device according to an embodiment of the present invention will be explained with reference to FIG. 30 and FIG. 31. In the present embodiment, configurations in which the semiconductor devices 10 explained in the first embodiment and the second embodiment are applied to a circuit of an organic EL display device will be described. Since the outline and the circuit configuration of the display device 20 are the same as those shown in FIG. 25 and FIG. 26, the description thereof will be omitted.

### [Pixel Circuit 301 of Display Device 20]

FIG. 30 is a circuit diagram showing a pixel circuit of a display device according to an embodiment of the present invention. As shown in FIG. 30, the pixel circuit 301 includes elements such as a drive transistor 11, a selection transistor 12, a storage capacitor 210, and a light-emitting element DO. The drive transistor 11 and the selection transistor 12 have the same configuration as the semiconductor device 10. The source electrode of the selection transistor 12 is connected to a signal line 211, and the gate electrode of the selection transistor 12 is connected to a gate line 212. The source electrode of the drive transistor 11 is connected to an anode power line 213, and the drain electrode of the drive transistor 11 is connected to one end of the light-emitting element DO. The other end of the light-emitting element DO is connected to a cathode power line 214. The gate electrode of the drive transistor 11 is connected to the drain electrode of the selection transistor 12. The storage capacitor 210 is connected to the gate electrode and the drain electrode of the drive transistor 11. A gradation signal for determining the light-emitting intensity of the light-emitting element DO is supplied to the signal line 211. A signal for selecting a pixel row in which the gradation signal described above is written is supplied to the gate line 212.

### [Cross-Sectional Structure of Display Device 20]

FIG. 31 is a cross-sectional diagram of a display device according to an embodiment of the present invention. Although the configuration of the display device 20 shown in FIG. 31 is similar to the display device 20 shown in FIG. 28, the configuration above the insulating layer 360 of the display device 20 in FIG. 31 is different from the structure above the insulating layer 360 of the display device 20 in FIG. 28. Hereinafter, in the configuration of the display device 20 in FIG. 31, descriptions of the same configuration as the display device 20 in FIG. 28 are omitted, and differences between the two will be explained.

As shown in FIG. 31, the display device 20 has the pixel electrode 390, a light-emitting layer 392, and a common electrode 394 (the light-emitting element DO) above the insulating layer 360. The pixel electrode 390 is arranged above the insulating layer 360 and inside the opening 381. An insulating layer 362 is arranged above the pixel electrode 390. An opening 363 is arranged in the insulating layer 362. The opening 363 corresponds to a light-emitting region. That is, the insulating layer 362 defines a pixel. The light-emitting layer 392 and the common electrode 394 are arranged above the pixel electrode 390 exposed by the opening 363. The pixel electrode 390 and the light-emitting layer 392 are individually arranged for each pixel. On the other hand, the common electrode 394 is arranged in common for the plurality of pixels. Different materials are used for the light-emitting layer 392 depending on the display color of the pixel.

In the third embodiment and fourth embodiment, although the configurations in which the semiconductor devices explained in the first embodiment and the second embodiment was applied to a liquid crystal display device and an organic EL display device was exemplified, the semiconductor device may be applied to display devices (for example, a self-luminous display device or an electronic paper display device other than an organic EL display device) other than these display devices. In addition, the semiconductor device described above can be applied without any particular limitation from a small sized display device to a large sized display device.

### EXAMPLES

First, a dependence of the thickness T3 of the titanium-containing layer of the gate electrode 160 on electrical characteristics of the semiconductor device 10 of the above embodiment will be explained.

### [Electrical Characteristics of Semiconductor Device 10]

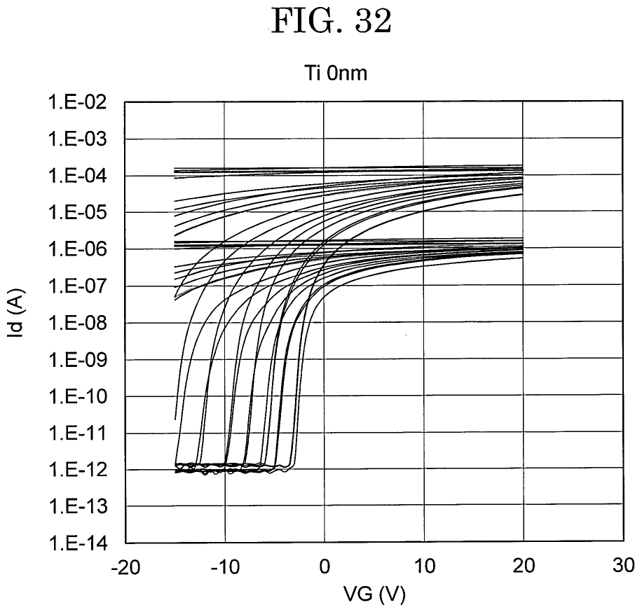

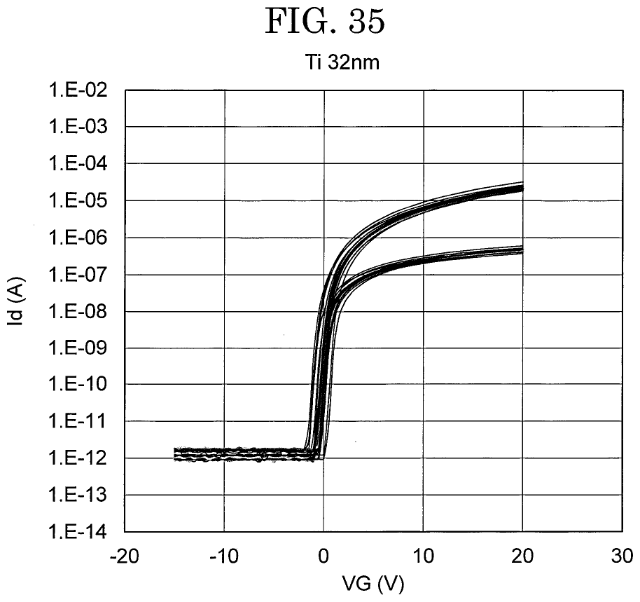

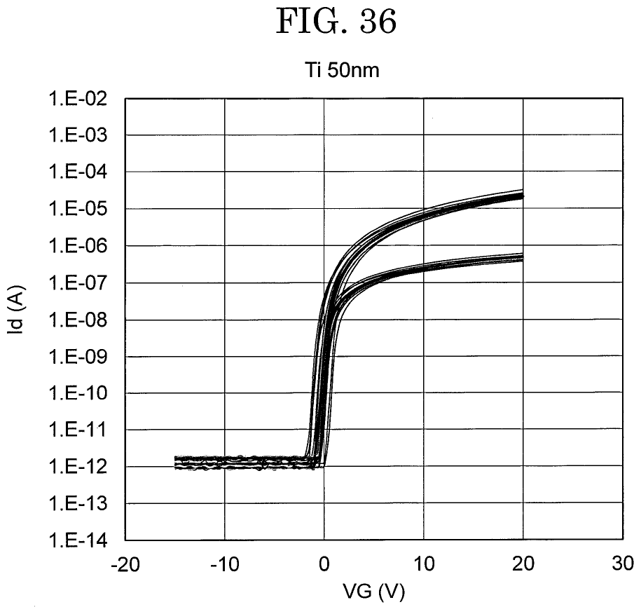

The electrical characteristics of the semiconductor device 10 according to the embodiment will be described with reference to FIG. 32 to FIG. 37. FIG. 32 to FIG. 37 indicate electrical characteristics of a semiconductor device according to an embodiment of the present invention. The electrical characteristics shown in FIG. 30 are the electrical characteristics of the semiconductor device 10 shown in the first embodiment. The electrical characteristics shown of the semiconductor device in FIG. 32 to FIG. 37 are the electrical characteristics of the semiconductor device 10 shown in the second embodiment.

### [Initial Characteristics]

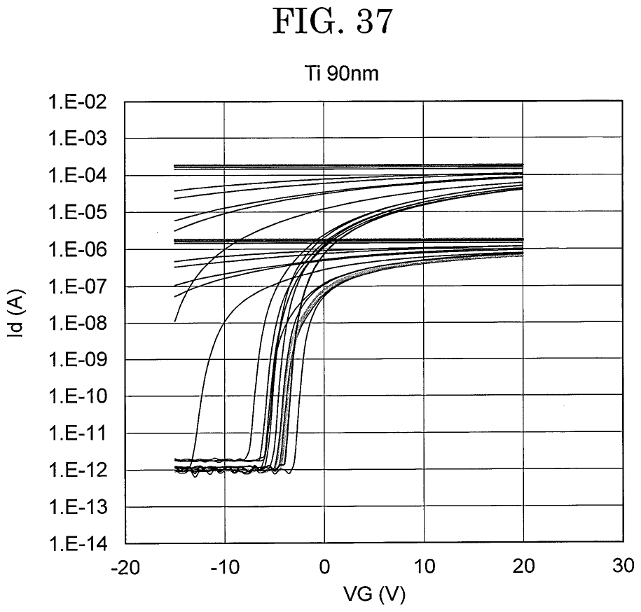

The measurement conditions for the electrical characteristics shown in FIG. 32 and FIG. 37 are as follows.
Size of the channel region CH: W/L=6.0 μm/3.0 μm
Source and drain voltage: 0.1 V (dotted line), 10 V (solid line)
Gate voltage: −15 V to +15 V
Measurement environment: room temperature, dark room
Thickness of oxide semiconductor layer (IGZO): 30 nm
Thickness of gate insulating layer (silicon oxide): 125 nm
Thickness of titanium-containing layer (titanium): 0 nm, 7 nm, 25 nm, 32 nm, 50 nm, and 90 nm
Thickness of molybdenum-tungsten layer: 300 nm
Measurement points: 20 points on the substrate surface

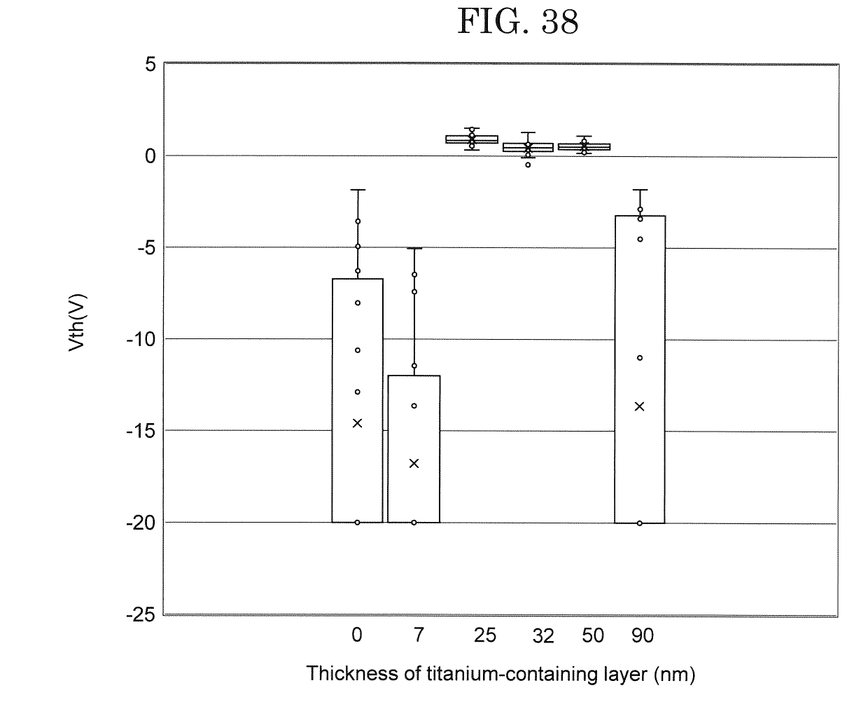

The electrical characteristics (Id-Vg characteristics) and mobility of the semiconductor device 10 are shown in FIG. 32 and FIG. 37. The horizontal axis is a gate voltage Vg and the vertical axis is a drain current (Id). FIG. 32 to FIG. 37 each correspond to a titanium-containing layer thickness T3 of 0 nm, 7 nm, 25 nm, 32 nm, 50 nm, and 90 nm, respectively. FIG. 38 shows the in-plane variation of the threshold voltage of the semiconductor device 10.

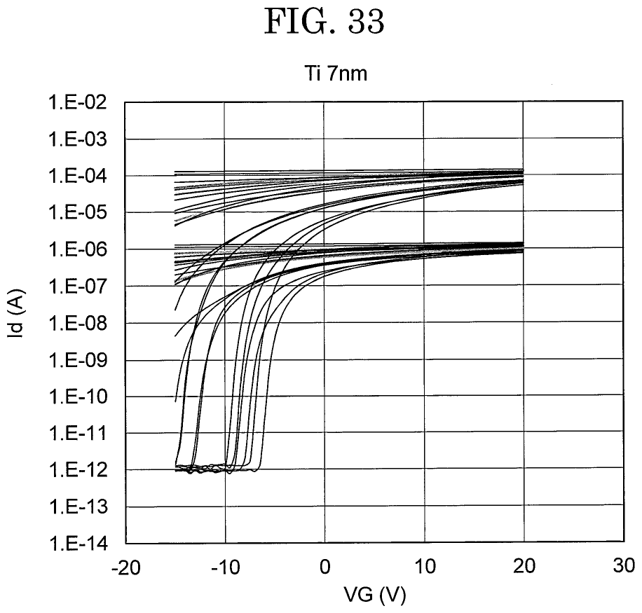

As shown in FIG. 32, FIG. 33, and FIG. 37, the in-plane variations were observed in the electrical characteristics of the transistors at 20 points when the thickness T3 of the titanium-containing layer was 0 nm, 7 nm, and 90 nm. It was observed that all of the electrical characteristics of the transistors exhibit so-called normally-on characteristics, in which the drain current Id begins to flow at a gate voltage Vg lower than 0V.

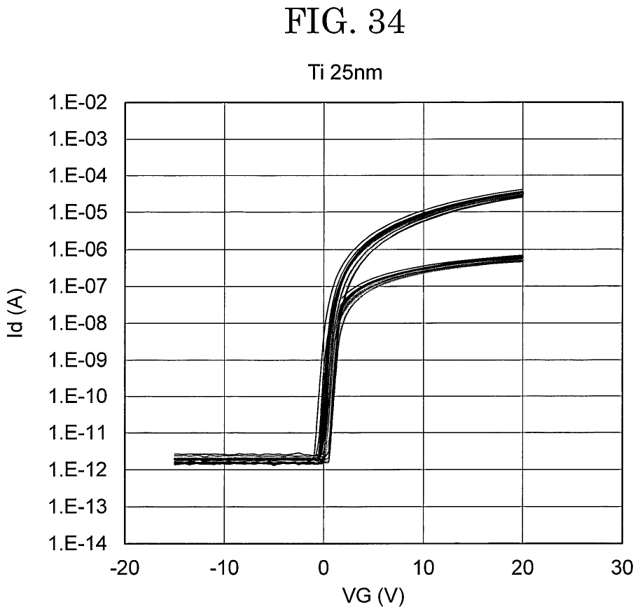

In contrast, as shown in FIG. 34 to FIG. 36, no in-plane variation was observed in the electrical characteristics of the transistors at 20 points when the thickness T3 of the titanium-containing layer was 25 nm, 32 nm, and 50 nm. It was also observed that the electrical characteristics of the transistors exhibit the so-called normally-off characteristics, in which the drain current Id begins to flow at a gate voltage Vg higher than 0V.

FIG. 38 shows the relationship between the thickness T3 of the titanium-containing layer of the gate insulating layer 150 and the threshold voltage of the semiconductor device. When the thickness T3 of the titanium-containing layer was 0 nm, 7 nm, and 90 nm, the electrical characteristics of the semiconductor device were confirmed to be normally-on, and normally-off characteristics were not obtained. In addition, in-plane variations in the threshold voltage of the semiconductor devices were observed. As shown in FIG. 38, it was confirmed that normally-on characteristics were exhibited when the thickness T3 of the titanium-containing layer was 25 nm, 32 nm, and 50 nm. It was also shown that the in-plane variation of the threshold voltage of the semiconductor device is suppressed.

It was shown that the thickness of the titanium-containing layer should be 50% or less of the thickness in the first region of the gate insulating layer.

Next, the results of the investigation of the dependence of the thickness of the gate insulating layer 150 on the electrical characteristics of the semiconductor device 10 according to the above embodiment will be described.

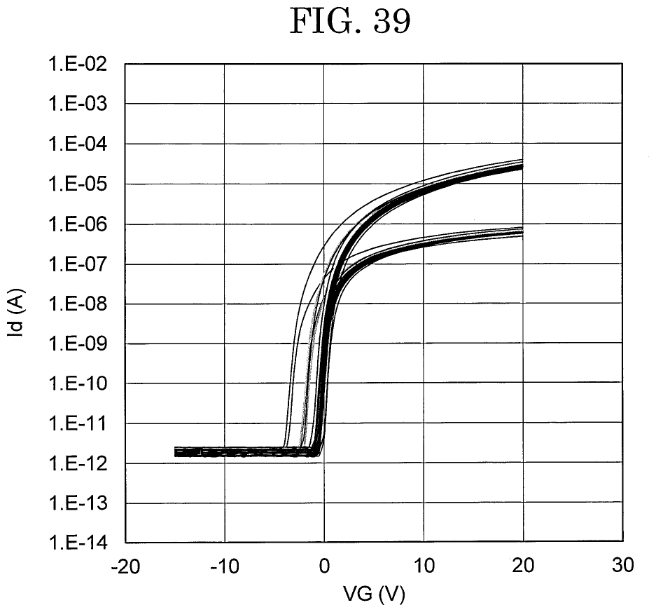

FIG. 39 to FIG. 42 illustrate the electrical characteristics of the semiconductor device 10 according to the above embodiment. FIG. 39 to FIG. 41 show the electrical characteristics of the semiconductor device according to an embodiment of the invention. The electrical characteristics shown in FIG. 39 to FIG. 41 are the electrical characteristics of the semiconductor device 10 shown in the first embodiment.

The measurement conditions for the electrical characteristics shown in FIG. 39 to FIG. 41 are as follows.
Size of the channel region CH: W/L=6.0 μm/2.0 μm
Source-drain voltage: 0.1 V (dotted line), 10 V (solid line)
Gate voltage: −15V to +15V
Measurement environment: room temperature, dark room
Thickness of oxide semiconductor layer (IGZO): 30 nm
Thickness of titanium-containing layer (titanium): 25 nm
Thickness of gate insulating layer (silicon oxide): 100 nm, 125 nm, and 150 nm
Thickness of molybdenum-tungsten layer: 300 nm
Measurement points: 20 points on the substrate surface

Here, the gate insulating layer thicknesses of 100 nm, 125 nm, and 150 nm are all thicknesses in the first region 152. The thickness T2 of the second region 154 of the gate insulating layer 150 was 75 nm, 100 nm, and 125 nm, respectively, due to dry etching when forming the gate electrode.

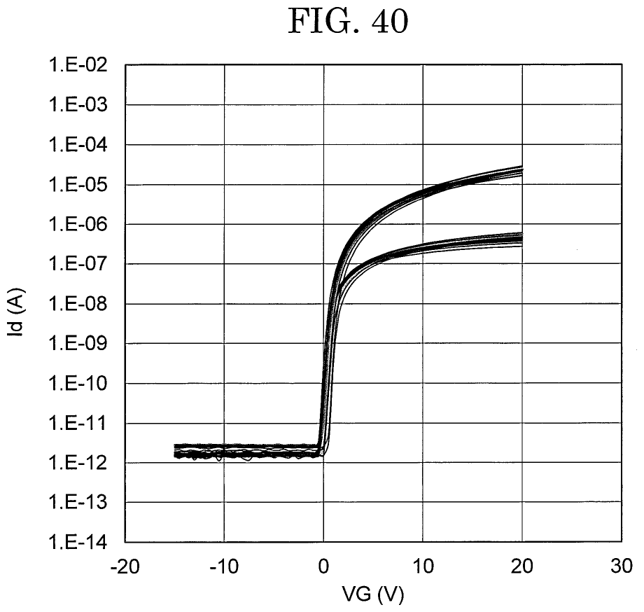

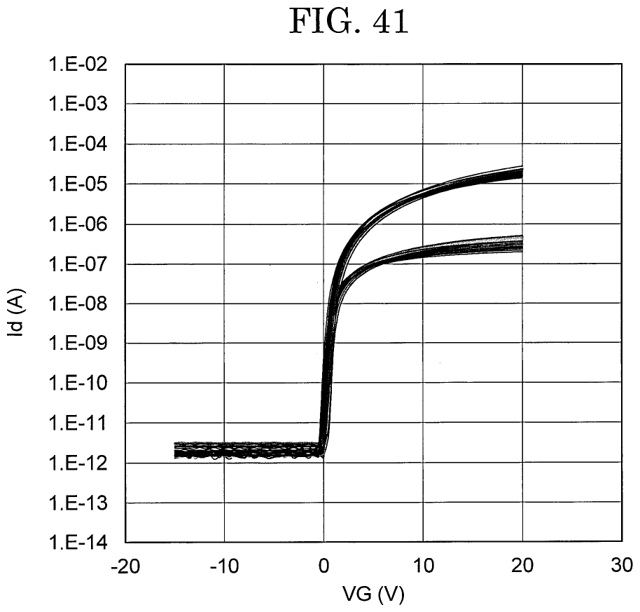

In FIG. 39 to FIG. 41, the electrical characteristics (Id-Vg characteristics) of the semiconductor device 10 are shown. The horizontal axis is the gate voltage Vg, and the vertical axis is the drain current (Id). In the semiconductor device shown in FIG. 39, the thickness of the first region of the oxide semiconductor layer 140 is 100 nm and the thickness of the second region is 75 nm. In the semiconductor device shown in FIG. 40, the thickness of the first region of the oxide semiconductor layer 140 is 125 nm and the thickness of the second region is 100 nm. In the semiconductor device shown in FIG. 41, the thickness of the first region of the oxide semiconductor layer 140 is 150 nm and the thickness of the second region is 125 nm.

In FIG. 41, variation in the on-current of the semiconductor device was observed within the substrate plane. The thickness T2 of the second region 154 of the gate insulating layer 150 of the semiconductor device in FIG. 41 is 125 nm, which exceeds 100 nm. Therefore, it is considered that impurities were not uniformly added to the oxide semiconductor layer 140 within the substrate plane during ion implantation of the oxide semiconductor layer 140, and the resistance of the source region S and the drain region D became non-uniform within the substrate plane. In particular, in the region where the oxide semiconductor layer 140 overlaps the tapered portion of the gate electrode 105, it is equivalent to an effective increase in the thickness of the gate insulating layer 150. In other words, in the region where the oxide semiconductor layer 140 overlaps the tapered portion of the gate electrode 105, impurities are not sufficiently added, and the resistance of the source region S and the drain region D is considered to have become non-uniform within the substrate plane. This is believed to have caused variation in the on-current of the semiconductor device within the substrate plane.

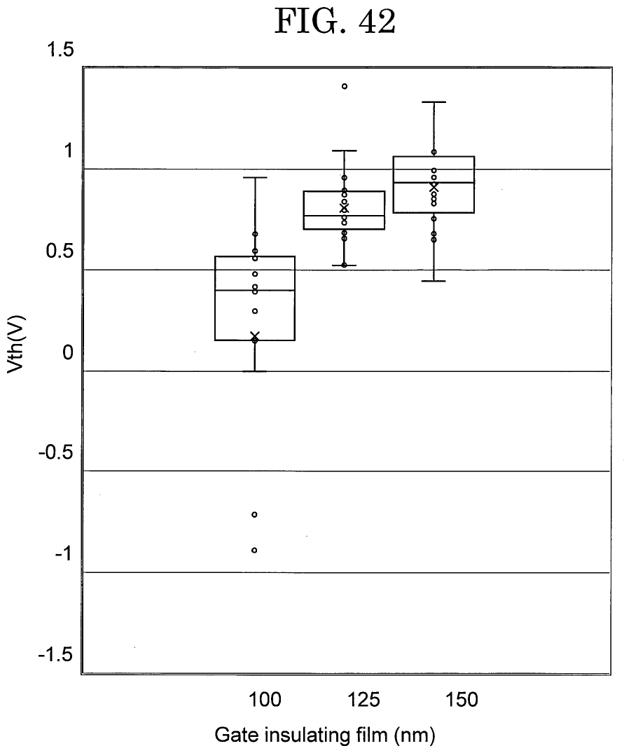

FIG. 42 shows the relationship between the thickness T1 of the first region 152 of the gate insulating layer 150 and the threshold voltage of the semiconductor device. When the thickness T1 of the first region 152 is less than 100 nm, the electrical characteristics of the semiconductor device are normally on and normally-off. As shown in FIG. 42, when the thickness T1 of the first region 152 is 100 nm or more, the drain current Id begins to flow at a gate voltage Vg lower than 0 V, the so-called normally-on characteristic.

As explained above, there is a correlation between the thickness of the titanium-containing layer 162 and the thickness of the gate insulating layer 150 of the semiconductor device. Considering the relationship between the thickness of the titanium-containing layer 162 and the thickness of the gate insulating layer 150, the thickness of the titanium-containing layer should be 50% or less of the thickness of the gate insulating layer in the first region. The thickness of the titanium-containing layer should be 25% or more and less than 70% of the thickness of the gate insulating layer in the second region. According to the semiconductor device according to an embodiment of the present invention, the semiconductor device has normally-off electrical characteristics and the variation of the electrical characteristics within the substrate plane can be suppressed. By using such a semiconductor device in a display device, a good display device with suppressed variation can be provided.

Each of the embodiments described above as an embodiment of the present invention can be appropriately combined and implemented as long as no contradiction is caused. In addition, the addition, deletion, or design change of components, or the addition, deletion, or condition change of processes as appropriate by those skilled in the art based on a semiconductor device and a display device of each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
an oxide semiconductor layer provided above an insulating surface;
a gate insulating layer provided above the oxide semiconductor layer; and
a gate electrode provided above the oxide semiconductor layer via the gate insulating layer,
wherein
the gate electrode has a titanium-containing layer and a conductive layer in order from the gate insulating layer side,
the gate insulating layer includes a first region overlapping the gate electrode and a second region not overlapping the gate electrode, and
a thickness of the titanium-containing layer is 50% or less than a thickness of the gate insulating layer in the first region.

2. The semiconductor device according to claim 1, wherein
the thickness of the titanium-containing layer is 25 nm or more and 50 nm or less.

3. The semiconductor device according to claim 1, wherein
a thickness of the first region of the gate insulating layer is 100 nm or more and 125 nm or less.

4. The semiconductor device according to claim 1, wherein
the thickness of the titanium-containing layer is 25% or more and less than 70% of the thickness of the gate insulating layer in the second region.

5. The semiconductor device according to claim 1, wherein
a thickness of the second region of the gate insulating layer is 75 nm or more and 100 nm or less.

6. The semiconductor device according to claim 1, wherein
the titanium-containing layer is a titanium layer.

7. The semiconductor device according to claim 1, wherein
the titanium-containing layer includes a titanium layer and a titanium nitride layer.

8. The semiconductor device according to claim 1, further comprising:
an aluminum-based metal oxide layer provided over the insulating surface in contact with a bottom of the oxide semiconductor layer.

9. The semiconductor device according to claim 1, wherein
the oxide semiconductor layer contains two metallic elements including indium, and
a ratio of indium in the oxide semiconductor layer is 50% or more.
